(19) United States
(12) Patent Application Publication
(10) Pub. No.: US 2026/0176413 A1
(43) Pub. Date: Jun. 25, 2026

(54) CURABLE COMPOSITIONS, COMPOSITES, METHODS OF MANUFACTURING COMPOSITES, AND SEMICONDUCTOR PACKAGES AND ELECTRONIC DEVICES INCLUDING THE SAME

(71) Applicants: Samsung Electronics Co., Ltd., Suwon-si (KR); Konkuk University Industry-Academic Cooperation Foundation, Seoul (KR)

(72) Inventors: Kyeong Pang, Suwon-si (KR); Munju Goh, Seoul (KR); In KIM, Suwon-si (KR); Youngwoo Cha, Seoul (KR); Younggi Hong, Seoul (KR)

(21) Appl. No.: 19/216,979

(22) Filed: May 23, 2025

(30) Foreign Application Priority Data
May 24, 2024 (KR) 10-2024-0068000

(51) Int. Cl. C08G 59/56; C08L 63/00; C08L 83/04; H10W 90/00

(52) U.S. Cl. CPC C08G 59/56; C08L 63/00; C08L 83/04; H10W 90/734; H10W 90/756

(57) ABSTRACT

Disclosed are a curable composition, a composite, a method of manufacturing the composite, and a semiconductor package and an electronic device including the composite, the curable composition including a first compound, wherein the first compound is an epoxy group-containing compound including a first functional group, a second compound, wherein the second compound is a cyclic group-containing compound including a second functional group, and curing agent, wherein one of the first functional group or the second functional group includes a hydrogen bond accepting group, and the other of the first functional group or the second functional group includes a hydrogen bond donating group, the first functional group and the second functional group form a hydrogen bond with each other, and the second compound has a molecular weight of about 160 grams per mole to about 400 grams per mole, as determined by gel permeation chromatography.

### CROSS-REFERENCE TO RELATED APPLICATION

This application claims priority to and the benefit of Korean Patent Application No. 10-2024-0068000, filed in the Korean Intellectual Property Office on May 24, 2024, and all the benefits accruing therefrom under 35 U.S.C. § 119, the entire content of which is herein incorporated by reference.

### BACKGROUND

### 1. Field

Curable compositions, composites, methods of manufacturing the composites, and semiconductor packages and electronic devices including the composite are disclosed.

### 2. Description of the Related Art

As semiconductors become lighter, thinner, and smaller in size with the continuing development of electronic devices, the corresponding semiconductor circuits become more complex with ever increasing circuit density. As a result of this trend to smaller size and greater density, electrical, thermal, and mechanical stability of a molding material becomes a more important factor, e.g., for device stability (reliability) and/or performance. In particular, heat generation is a problem often present in an application processor (AP) of mobile products and the heat may have a significant impact on performance and reliability of the mobile products.

Molding is a process of sealing semiconductors by using a molding composition, which includes a method of making a semiconductor package to protect a semiconductor chip from the external environment, e.g., oxygen or moisture as well as other contaminants, to electrically insulate the semiconductor chip, and to effectively dissipate heat during operation of the chip. In particular, a molding protects the semiconductor chip that includes wire bonding or flip chip bonding from electrical deterioration by various causes such as corrosion in air, moisture, or the like, to effectively dissipate heat generated during operation, and to also provide sufficient mechanical stability to the chip.

In general, the semiconductor package uses an epoxy molding compound or composition (EMC), which is a thermosetting resin, as a molding material. However, present EMCs have limitations in terms of coefficient of thermal expansion (CTE), warpage, and thermal conductivity, and in order to overcome these limitations, large amounts of high thermal conductivity inorganic filler may be used in the EMC.

However, even if the thermal conductivity of the high thermal conductivity inorganic filler is increased to above 100 Watts per meter-Kelvin (W/mK), there is a limit to the increase in the thermal conductivity of the composite material (cured product), and in particular, for EMC, it is impossible to apply an inorganic filler of 90 weight percent (wt %) or more, and thus sufficient thermal conductivity cannot be obtained. In addition, as the filler loading amount increases, the mechanical properties are known to deteriorate or degrade. Therefore, there is a need for a solution that can secure high thermal conductivity without deteriorating the mechanical properties.

Hence, there is a demand for the development of high thermal conductivity materials that may be applied not only to semiconductors but also to various electrical and electronic fields where good heat dissipation characteristics are desired.

### SUMMARY

One or more embodiments provide a curable composition capable of improving the thermal conductivity and mechanical properties of a composite including a cured product, with superior melt flowability and processability due to its low viscosity and glass transition temperature.

One or more embodiments provide a composite including a cured product of the curable composition and a method for manufacturing the same.

One or more embodiments provide a semiconductor package and an electronic device including the composite.

According to an aspect, a curable composition includes:
a first compound, wherein the first compound is an epoxy group-containing compound comprising a first functional group,
a second compound, wherein the second compound is a cyclic group-containing compound comprising a second functional group, and
a curing agent,
wherein one of the first functional group or the second functional group includes a hydrogen bond accepting group, and the other of the first functional group or the second functional group includes a hydrogen bond donating group,
the first functional group and the second functional group form a hydrogen bond with each other, and
the second compound has a molecular weight of about 160 grams per mole (g/mol) to about 400 g/mol, as determined by gel permeation chromatography (GPC).

The first compound and the second compound may form a eutectic mixture at a temperature below the melting point of the first compound.

The first compound may be represented by Chemical Formula 1.

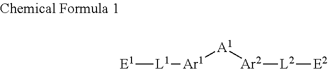

wherein, in Chemical Formula 1,
A¹ is —C(═O)—, —C(═O)O—, —OC(═O)—, —OC(═O)O—, —N═CR^{a}—, —N═N—, —CR^{b}═N—, —CR^{c}═CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c}, R^{d}, R^{e}, and R^{f} are each independently hydrogen, deuterium, a C1 to C10 alkyl group, or a C1 to C10 haloalkyl group,
L¹ and L² are each independently a single bond, —O—, —C(═O)—, —C(═O)O—, —OC(═O)—, —OC(═O)O—, —CR^{c}═CR^{d}—C(═O)—, —S(═O)—, —S(═O)₂—, —CH═N—, —NR^{e}C(═O)O—, —C(═O)NR^{f}—, or —OC(═O)NHS(═O)O— wherein R^{c}, R^{d}, R^{e}, and R^{f} are each independently hydrogen, deuterium, a C1 to C10 alkyl group, or a C1 to C10 haloalkyl group,
Ar¹ and Ar² are each independently a substituted or unsubstituted C6 to C30 arylene group, a substituted or unsubstituted C2 to C30 heteroarylene group, a substituted or unsubstituted C3 to C30 cycloalkylene group, C2 to C30 heterocycloalkylene group, or a combination thereof, and
E¹ and E² are each independently an epoxy-containing group.

In Chemical Formula 1, Ar¹ and Ar² may each independently be a moiety represented by one of Chemical Formulae (1A) to (1I).

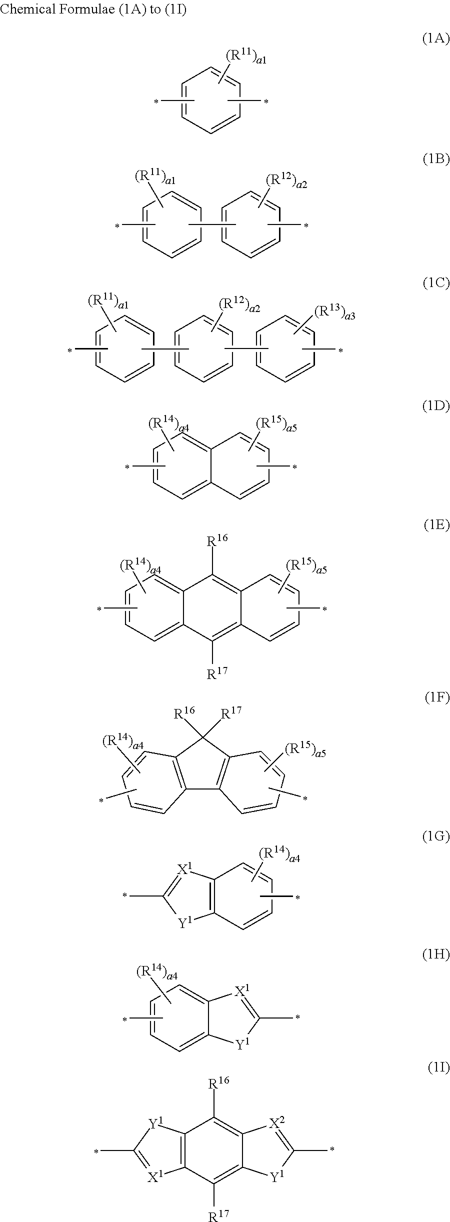

wherein, in Chemical Formulae (1A) to (1I),
R¹¹, R¹², R¹³, R¹⁴, R¹⁵, R¹⁶, and R¹⁷ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, and a3 are each independently an integer from 0 to 4,
a4 and a5 are each independently an integer from 0 to 3, and
* indicates a linking point with Chemical Formula 1.

In Chemical Formula 1, Ar¹¹ and Ar¹² may be the same or different from each other.

In Chemical Formula 1, the L¹-Ar¹ bond and Ar¹-A¹ bond may be at a meta position or at a para position to each other, and the L²-Ar² and the Ar²-A¹ may be at a meta position or at a para position to each other.

In Chemical Formula 1, the epoxy-containing group (E¹ and E²) may be represented by Chemical Formula 2.

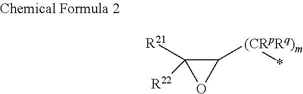

wherein, in Chemical Formula 2,
R²¹ and R²² are each independently hydrogen, deuterium, a halogen, a C1 to C10 alkyl group, or a C1 to C10 haloalkyl group,
R^{p} and R^{q} are each independently hydrogen, deuterium, a halogen, a C1 to C10 alkyl group, or a C1 to C10 haloalkyl group, and
m is an integer from 1 to 10.

In Chemical Formula 2, when m is 2 or more, non-adjacent —CR^{p}R^{q}— may be replaced with oxygen (—O—).

The epoxy-containing group of Chemical Formula 2 may be a functional group represented by one of Chemical Formulae (2A) to (2H).

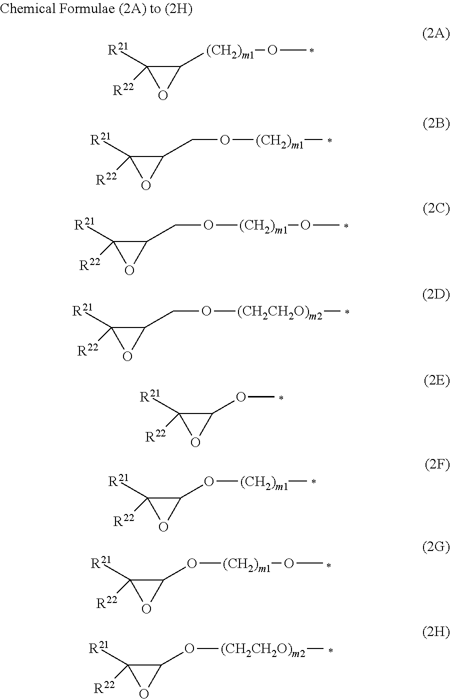

wherein, in Chemical Formulae (2A) to (2H),
R²¹ and R²² are each independently hydrogen, deuterium, a halogen, a C1 to C10 alkyl group, or a C1 to C10 haloalkyl group, and
m1 and m2 are each independently an integer from 1 to 5.

The first compound may be a compound represented by Chemical Formula 3 or Chemical Formula 4.

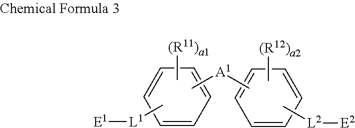

wherein, in Chemical Formula 3,
A¹, L¹, L², E¹, and E² are the same as described in Chemical Formula 1,
R¹¹ and R¹² are each independently hydrogen, deuterium, a C1 to C10 alkyl group, or a C1 to C10 haloalkyl group, and
a1 and a2 are each independently an integer from 0 to 4.

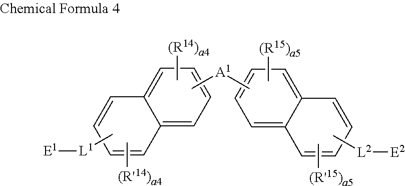

wherein, in Chemical Formula 4,
A¹, L¹, L², E¹, and E² are the same as described in Chemical Formula 1,
R¹⁴, R¹⁵, R′¹⁴, and R′¹⁵ are each independently hydrogen, deuterium, a C1 to C10 alkyl group, or a C1 to C10 haloalkyl group, and
a4 and a5 are each independently an integer from 0 to 3.

The second compound may be represented by Chemical Formula 5.

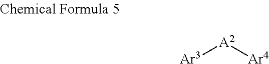

wherein, in Chemical Formula 5,
A² is a functional group capable of forming a hydrogen bond with A¹ in Chemical Formula 1 and includes —N(H)—, —O(H)—, —S(H)—, C(═O)—, —C(═O)O—, —OC(═O)—, —OC(═O)O—, —N═CR^{a}—, —N═N—, —CR^{b}—N—, —CR^{c}—CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c}, R^{d}, R^{e}, and R^{f} are each independently hydrogen, deuterium, a C1 to C10 alkyl group, or a C1 to C10 haloalkyl group, and
Ar³ and Ar⁴ are each independently a substituted or unsubstituted C6 to C30 aryl group, C2 to C30 heteroaryl group, a substituted or unsubstituted C3 to C30 cycloalkyl group, C2 to C30 heterocycloalkyl group, or a combination thereof.

In Chemical Formula 5, Ar³ and Ar⁴ may each independently be a moiety represented by one of Chemical Formulae (5A) to (5I).

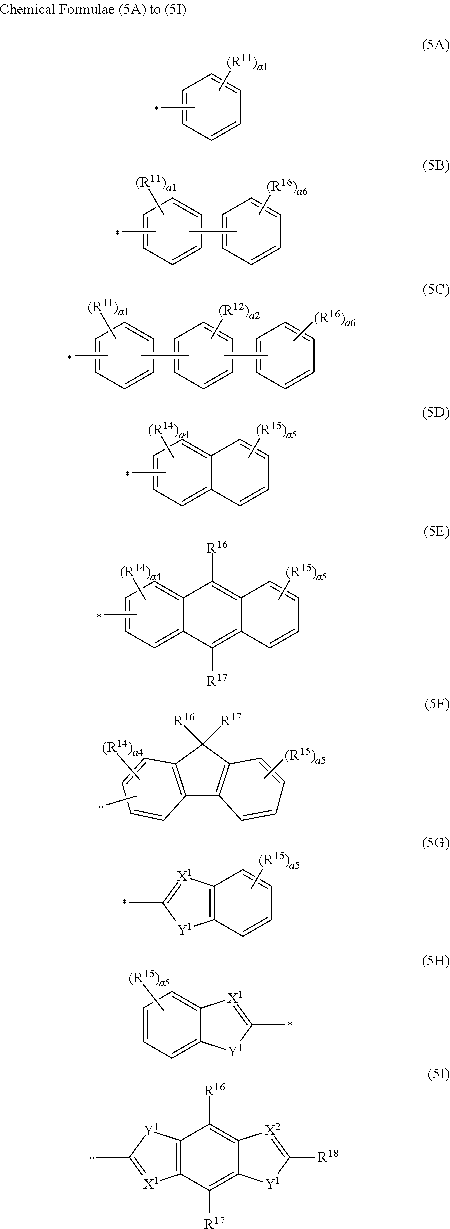

wherein, in Chemical Formulae (5A) to (5I),
R¹¹, R¹², R¹³, R¹⁴, R¹⁵, R¹⁶, R¹⁷, and R¹⁸ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, a3, and a5 are each independently an integer from 0 to 4,
a4 is an integer from 0 to 3,
a6 is an integer from 0 to 5, and
* indicates a linking point with Chemical Formula 5.

The second compound may have a compound length of about 8.0 angstroms (Å) to about 25 Å, as determined by Density Functional Theory.

The first compound may be included in the curable composition in an amount of about 30 mole percent (mol %) to about 60 mol %, based on a total of 100 mol % of the first compound and the second compound.

The curable composition may have a glass transition (melting) temperature of about −30° C. to about 50° C.

The eutectic mixture of the first compound and the second compound may have a complex viscosity of less than or equal to about 10 Pascal seconds (Pas) at a temperature of less than or equal to about 100° C., as determined by a rheometer at a heating rate of 2° C./min, a strain of 5%, and an angular frequency of 1 Hertz.

The curing agent may include an aliphatic amine, an aromatic amine, an alicyclic amine, or a combination thereof.

The curable composition may include about 10 to about 90 parts by weight, for example, about 30 to about 60 parts by weight of the curing agent based on 100 parts by weight of a total amount of the first compound and the second compound.

A curing temperature of the curing agent may be about 25° C. to about 250° C., for example about 60° C. to about 180° C., or about 25° C. to about 130° C.

The curable composition may show an exothermic peak with an onset temperature from about 25 to about 130° C. in a differential scanning calorimetry (DSC) graph, and an endothermic peak may not substantially appear in the temperature range where the exothermic peak is shown.

The curable composition may have a complex viscosity of less than or equal to about 400 Pa·s, for example about 40 Pa·s to about 200 Pa·s, or about 60 Pa·s to about 150 Pa·s at a temperature of about 100° C. or less, as determined by a rheometer at a heating rate of 2° C./min, a strain of 5%, and an angular frequency of 1 Hertz.

The curable composition may further include a filler.

As used herein, the filler may include an inorganic filler, an organic filler, or a combination thereof.

The inorganic filler may include a metal, a metal alloy, an oxide, a nitride, an oxynitride, a carbonate, a clay, a glass fiber, a ceramic, or a combination thereof.

Examples of the inorganic filler may include a metal such as gallium (Ga), indium (In), tin (Sn), silver, copper, gold, aluminum, nickel, zinc, and an alloy of two or more of the metals, silica, boron oxide, alumina, magnesia, alumina (Al₂O₃), zinc oxide (ZnO), magnesium oxide (MgO), titania (TiO₂), antimony oxide, silicon nitride, boron nitride (BN, for example hexagonal boron nitride or boron nitride nanotubes), aluminum nitride (AlN), carbon nitride, silicon oxynitride, boron oxynitride, calcium silicate, calcium carbonate, magnesium carbonate, clay, talc, glass fiber, eucryptite ceramic, diamond, carbon nanotubes (CNT), graphene, graphene oxide, reduced graphene oxide, or a combination thereof.

The filler may be included in the curable composition in an amount of about 40 to about 95 wt %, about 40 to about 60 wt %, or about 80 to about 95 wt %, based on 100 wt % of the curable composition.

The curable composition including the filler may have a complex viscosity of less than or equal to about 400 Pa·s, for example about 100 Pa·s to about 200 Pa·s at a temperature of 100° C. or less, as determined by a rheometer at a heating rate of 2° C./min, a strain of 5%, and an angular frequency of 1 Hertz.

Another embodiment provides a composite including a cured product of the aforementioned curable composition, and optionally a filler.

The composite may have a thermal conductivity of greater than or equal to about 0.35 Watts per meter-Kelvin (W/mK) and less than or equal to about 16 W/mK, as measured by a Transient Plane Source method in an isotropic mode.

The curable composition may further include at least one additive that may be a curing accelerator, a reaction regulator, a release agent, a coupling agent, a stress reliever, or an auxiliary flame retardant, but embodiments are not limited thereto.

According to another embodiment, a method for manufacturing a composite includes curing a curable composition including the aforementioned curable composition and optionally a filler at a temperature of about 25° C. to about 250° C.

According to another embodiment, a semiconductor package including the composite is provided.

The semiconductor package includes:
a substrate,
at least one chip mounted on the substrate,
a connection portion for electrically connecting at least one chip and the substrate, and
a molding portion configured to encapsulate at least one chip on the substrate,
wherein the molding portion includes a composite manufactured using the curable composition as described herein.

According to another embodiment, an electronic device including the composite manufactured using the curable composition as described herein is provided.

The curable composition has a phase transition temperature lower than the melting point of the first compound and the melting point of the second compound, thereby lowering the phase transition temperature and viscosity, and thus allowing excellent melt flowability and processability.

The composite including the cured product of the curable composition as described herein has excellent mechanical strength and thermal conductivity, and may be used in semiconductor packages and electronic devices.

### BRIEF DESCRIPTION OF THE DRAWINGS

FIG. 1 is a cross-sectional view showing a schematic configuration of a semiconductor package according to one or more embodiments.

FIG. 2 is a cross-sectional view showing a schematic configuration of an integrated circuit device according to one or more embodiments.

FIG. 3 is a plan view illustrating a schematic configuration of an integrated circuit device according to one or more embodiments.

FIG. 4 is a diagram illustrating a schematic configuration of an integrated circuit device according to one or more embodiments.

FIG. 5 is a diagram schematically illustrating a mobile wireless phone according to one or more embodiments.

FIG. 6 is a graph of heat flow (mW) versus temperature (° C.) and shows the results of differential scanning calorimetry (DSC) measurement of the curable composition according to Comparative Example 1.

FIG. 7 is a graph of heat flow (mW) versus temperature (C) and shows the results of DSC measurement of the curable composition according to Example 5B.

### DETAILED DESCRIPTION

Advantages and characteristics of this disclosure, and a method for achieving the same, will become evident referring to the following example embodiments together with the drawings. The disclosure, however, is not limited to the embodiments disclosed, and may be embodied or implemented in many different forms different, and therefore, should not be construed as limited to the embodiments set forth herein. Like reference numerals refer to like elements throughout. The present embodiments are provided to complete the present disclosure, and to fully inform the scope of the disclosed subject matter to those skilled in the art to which the present invention pertains, and the subject matter is only defined by the scope of the claims.

Unless otherwise defined, all terms (including technical and scientific terms) as used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

The terminology as used herein is for the purpose of describing particular embodiments only and is not intended to be limiting. As used herein, the singular forms “a,” “an,” and “the” are intended to include the plural forms, unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, “at least one of A, B, or C,” “one of A, B, C, or a combination thereof” and “one of A, B, C, and a combination thereof” refer to each constituent element, and a combination thereof (e.g., A; B; C; A and B; A and C; B and C; or A, B and C).

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

As used herein, when a definition is not otherwise provided, “substituted” refers to replacement of hydrogen atom of a compound or a functional group by a substituent selected from a halogen atom, a hydroxy group, a nitro group, a cyano group, an amino group, an azido group, an amidino group, a hydrazine group, a hydrazone group, a carbonyl group, a carbamyl group, a thiol group, an ester group, a carboxylic acid group or a salt thereof, a sulfonic acid group or a salt thereof, a phosphoric acid group or a salt thereof, a silyl group, a C1 to C20 alkyl group, a C1 to C20 alkoxy group, a C2 to C20 alkenyl group, a C2 to C20 alkynyl group, a C6 to C30 aryl group, a C7 to C30 arylalkyl group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. Moreover, the carbon atoms provided by the substituent, if present, is exclusive of the stated number of carbon atoms in the hydrocarbon groups that follow or are recited in the claims.

Unless otherwise defined, “halogen” means F, Cl, Br, or I, and “haloalkyl group” is one in which at least one hydrogen atom of an alkyl group is substituted with a halogen (e.g., CF₃, CHF₂, CH₂F, CCl₃, or the like). Non-limiting examples of “haloalkyl group” include monohaloalkyl groups and polyhaloalkyl groups such as dihaloalkyl groups, perhaloalkyl groups, or the like. The monohaloalkyl group is an alkyl group substituted with one iodine, bromine, chlorine, or fluorine in the alkyl group, and the dihaloalkyl group and the polyhaloalkyl group mean an alkyl group substituted with two or more identical or different halogen atoms.

Unless otherwise defined, “hetero” as used herein means containing 1 to 4 heteroatoms selected from B, N, O, S, Se, Te, Si, and P.

Unless otherwise defined, “alkyl group” as used herein refers to a fully saturated straight or branched chain hydrocarbon group.

Non-limiting examples of the “alkyl group” may include a methyl group, an ethyl group, an n-propyl group, an isopropyl group, an n-butyl group, an isobutyl group, a sec-butyl group, an n-pentyl group, an isopentyl group, a neopentyl group, an iso-amyl group, an n-hexyl group, a 3-methylhexyl group, a 2,2-dimethylpentyl group, a 2,3-dimethylpentyl group, an n-heptyl group, or the like. At least one hydrogen atom in the alkyl group may be substituted as defined herein.

Unless otherwise defined, “alkoxy group” as used herein represents alkyl-O—, and the alkyl is the same as described herein. Non-limiting examples of the alkoxy group may include a methoxy group, an ethoxy group, a propoxy group, a 2-propoxy group, a butoxy group, a tert-butoxy group, a pentyloxy group, a hexyloxy group, a cyclopropoxy group, a cyclohexyloxy group, or the like. At least one hydrogen atom in the alkoxy group may be substituted with the same substituent as in the case of the above-described alkyl group.

Unless otherwise defined, “alkenyl group” as used herein refers to a hydrocarbon group formed by substituting at least one carbon-carbon double bond in the middle or at the terminus of the alkyl group, and non-limiting examples thereof include an ethenyl group, a propenyl group, a butenyl group, or the like.

Unless otherwise defined, “alkynyl group” as used herein refers to a hydrocarbon group formed by substituting at least one carbon-carbon triple bond in the middle or at the terminus of the alkyl group, and non-limiting examples thereof include an ethynyl group, a propynyl group, or the like.

Unless otherwise defined, “cycloalkyl group” as used herein refers to a monovalent saturated hydrocarbon group, and non-limiting examples thereof include a cyclopropyl group, a cyclobutyl group, a cyclopentyl group, a cyclohexyl group, a cycloheptyl group, or the like.

Unless otherwise defined, “heterocycloalkyl group” as used herein refers to a monovalent saturated group having at least one heteroatom selected from B, N, O, P, Si, S, Se, and Ge as a ring-forming atom, the remaining ring forming atoms being carbon, and non-limiting examples thereof include a tetrahydrofuranyl group, a tetrahydrothiophenyl group, or the like.

Unless otherwise defined, “cycloalkenyl group” as used herein refers to a monovalent cycloalkyl group that has at least one carbon-carbon double bond in the ring thereof and no aromaticity, and non-limiting examples thereof include a cyclopentenyl group, a cyclohexenyl group, a cycloheptenyl group, or the like.

Unless otherwise defined, “heterocycloalkenyl group” as used herein refers to a monovalent heterocycloalkyl group that has at least one double bond in its ring. Non-limiting examples thereof include a 2,3-dihydrofuranyl group, a 2,3-dihydrothiophenyl group, or the like.

Hereinafter, as used herein, when a definition is not otherwise provided, “arylene group” and “aryl group,” as used alone or in combination, refers to a divalent aromatic hydrocarbon group containing one or more rings. The “arylene group” and “aryl group” also include groups in which an aromatic ring is fused to one or more cycloalkyl rings. Non-limiting examples of the “arylene group” include a phenylene group, a naphthalene group, a tetrahydronaphthalene group, or the like, and non-limiting examples of the “aryl group” include a phenyl group, a naphthyl group, a tetrahydronaphthyl group, or the like. At least one hydrogen atom in the aryl group and the arylene group may be substituted with the same substituent as in the case of the above-described alkyl group.

As used herein, “alkylaryl group” refers to an aryl group substituted with at least one alkyl group.

Hereinafter, as used herein, when a definition is not otherwise provided, “heteroarylene group” and “heteroaryl group” refer to a monocyclic group or a bicyclic group containing one or more heteroatoms selected from B, N, O, P, Si, S, Se, or Ge and the remaining ring atoms being carbon atom(s). The heteroaryl group and the heteroarylene group may each include, for example, 1 to 5 heteroatoms, and 5 to 10 ring members.

Non-limiting examples of the monocyclic heteroarylene group may include a thienylene group, a pyrrolylene group, an imidazolylene group, a pyrazolylene group, a thiazolylene group, an isothiazolylene group, a 1,2,3-oxadiazolylene group, 1,2,4-oxadiazolylene group, a 1,2,5-oxadiazolylene group, a 1,3,4-oxadiazolylene group, a 1,2,3-thiadiazolylene group, a 1,2,4-thiadiazolylene group, a 1,2,5-thiadiazolylene group, a 1,3,4-thiadiazolylene group, an isothiazol-3-ylene group, an isothiazol-4-ylene group, an isothiazol-5-ylene group, an oxazol-2-ylene group, an oxazol-4-ylene group, an oxazol-5-ylene group, an isoxazol-3-ylene group, an isoxazol-4-ylene group, an isoxazol-5-ylene group, a 1,2,4-triazol-3-ylene group, a 1,2,4-triazol-5-ylene group, a 1,2,3-triazol-4-ylene group, a 1,2,3-triazole-5-ylene group, a tetrazolyl group, a pyrid-2-ylene group, a pyrid-3-ylene group, a 2-pyrazin-2-ylene group, a pyrazin-4-ylene group, a pyrazin-5-ylene group, a 2-pyrimidin-2-ylene group, a 4-pyrimidin-2-ylene group, a 5-pyrimidin-2-ylene group, or the like.

Non-limiting examples of the bicyclic heteroarylene group may include an indolylene group, an isoindolylene group, an indazolylene group, an indolizinylene group, a purinylene group, a quinolizinylene group, a quinolinylene group, an isoquinolinylene group, a cinnolinylene group, or the like.

As used herein, “alkyl heteroaryl group” refers to a heteroaryl group substituted with at least one alkyl group.

Hereinafter, a curable composition (e.g., molding compositions for semiconductor packages) according to example embodiments, a composite including a cured product of the curable composition, a method for producing composite, and a semiconductor package and an electronic device using the same will be described in further detail.

Epoxy resins, which are currently used as molding materials for electronic devices such as semiconductor devices, often do not have sufficient thermal conductivity, and thus may be unable to dissipate all of the heat generated during the use of electronic products. In addition, fillers added to increase thermal conductivity are not added in sufficient amounts due to the high viscosity of epoxy resins. In particular, in the case of high thermal conductivity liquid crystal epoxy, there is a problem that increasing the processing temperature to reduce the processing viscosity increases the energy consumption required for the process. In addition, as the pitch of semiconductor devices becomes smaller, lower viscosity must be secured in order to apply it to underfill (UF) or moldable underfill (MUF).

The curable composition may be prepared by mixing an epoxy resin and a curing agent. In order to ensure uniform mixing, it is recommended to stir the epoxy resin and the curing agent while they are both in a liquid state. Therefore, in the case of solid epoxy resin, stirring is performed while maintaining a temperature higher than the melting point of the epoxy resin in order to maintain the liquid state. However, since the curing reaction may occur during the stirring process when the mixture of epoxy resin and curing agent is heated above the melting point of the epoxy resin, it is inevitable to select a curing agent that initiates the curing reaction at a temperature exceeding the melting point of the epoxy resin. This results in a lot of energy being used for heating to maintain the temperature during the stirring and curing process, which can result in lower economic efficiency.

According to a curable composition according to one or more embodiments, by applying a solid-state epoxy compound and a compound capable of inducing a hydrogen bond with the epoxy compound, a (liquid) eutectic liquid is formed, thereby lowering the viscosity, thereby providing excellent processability in processes such as stirring and transporting, and no pores or poor mixing are generated when the eutectic mixture and the curing agent are mixed. Even if a sufficient amount of filler is mixed, high dispersibility and filling rate may be secured, thereby improving the thermal conductivity of the cured product, and further, by lowering the phase transition temperature of the curable composition, various curing agents that start the curing reaction at a lower temperature than curing agents previously used may be used.

A curable composition according to an aspect includes a mixture including a first compound, wherein the first compound is an epoxy group-containing compound including a first functional group, and a second compound, wherein the second compound is a cyclic group-containing compound including a second functional group; and a curing agent. One of the first functional group or the second functional group includes a hydrogen bond accepting group, and the other of the first functional group or the second functional group includes a hydrogen bond donating group, and the first functional group and the second functional group form a hydrogen bond with each other. The first functional group and the second functional group may form a hydrogen bond to stabilize energy and form a eutectic mixture, and the stable eutectic mixture has a reduced electrical interaction, thereby reducing the phase transition temperature of the curable composition.

In one or more embodiments, the first compound and the second compound may form a eutectic mixture at a temperature below the melting point of the first compound.

The first compound may be represented by Chemical Formula 1.

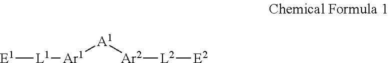

In Chemical Formula 1,
A¹ is —C(═O)—, —C(═O)O—, —OC(═O)—, —OC(═O)O—, —N═CR^{a}—, —N═N—, —CR^{b}═N—, —CR^{c}═CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c}, R^{d}, R^{e}, and R^{f} are each independently hydrogen, deuterium, a C1 to C10 alkyl group, or a C1 to C10 haloalkyl group,
L¹ and L² are each independently a single bond, —O—, —C(═O)—, —C(═O)O—, —OC(═O)—, —OC(═O)O—, —CR^{c}═CR^{d}—C(═O)—, —S(═O)—, —S(═O)₂—, —CH═N—, —NR^{e}C(═O)O—, —C(═O)NR^{f}—, or —OC(═O)NHS(═O)O— wherein R^{c}, R^{d}, R^{e}, and R^{f} are each independently hydrogen, deuterium, a C1 to C10 alkyl group, or a C1 to C10 haloalkyl group,
Ar¹ and Ar² are each independently a substituted or unsubstituted C6 to C30 arylene group (e.g., a substituted or unsubstituted C6 to C20 arylene group or a substituted or unsubstituted C6 to C10 arylene group), a substituted or unsubstituted C2 to C30 heteroarylene group (e.g., a substituted or unsubstituted C2 to C20 heteroarylene group or a substituted or unsubstituted C2 to C10 heteroarylene group), a substituted or unsubstituted C3 to C30 cycloalkylene group (e.g., a substituted or unsubstituted C3 to C20 cycloalkylene group or a substituted or unsubstituted C3 to C10 cycloalkylene group), C2 to C30 heterocycloalkylene group (e.g., a substituted or unsubstituted C2 to C20 heterocycloalkylene group or a substituted or unsubstituted C2 to C10 heterocycloalkylene group), or a combination thereof, and
E¹ and E² are each independently an epoxy-containing group.

In Chemical Formula 1, Ar¹ and Ar² may each independently be a phenylene group, a naphthalene group, an anthracene group, a diphenylene group, a triphenylene group, or a fluorene group.

In Chemical Formula 1, Ar¹ and Ar² may each independently be a moiety represented by one of Chemical Formulae (1A) to (1I).

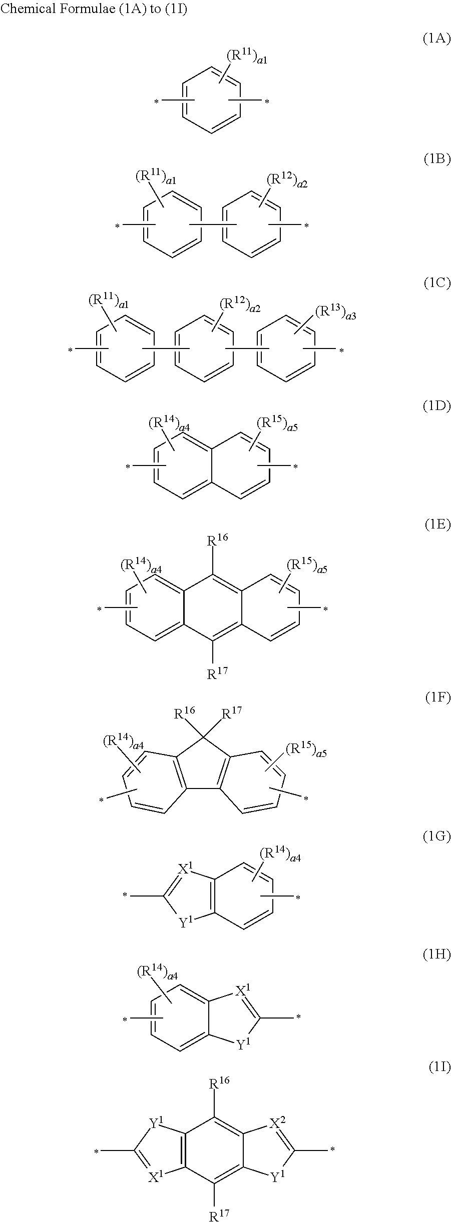

In Chemical Formulae (1A) to (1I),
R¹¹, R¹², R¹³, R¹⁴, R¹⁵, R¹⁶, and R¹⁷ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, and a3 are each independently an integer from 0 to 4,
a4 and a5 are each independently an integer from 0 to 3, and
* indicates a linking point with Chemical Formula 1.

In Chemical Formula 1, Ar¹ and Ar² may be the same or different from each other.

In Chemical Formula 1, the L¹-Ar¹ bond and the Ar¹-A¹ bond may be at the meta position or the para position to each other, and the L²-Ar² bond and the Ar²-A¹ may be at a meta position or a para position to each other.

In Chemical Formula 1, the epoxy-containing group (E¹ and E²) may be represented by Chemical Formula 2.

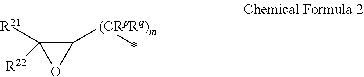

In Chemical Formula 2,
R²¹ and R²² are each independently hydrogen, deuterium, a halogen, a C1 to C10 alkyl group, or a C1 to C10 haloalkyl group,
R^{p} and R^{q} are each independently hydrogen, deuterium, a halogen, a C1 to C10 alkyl group, or a C1 to C10 haloalkyl group, and
m is an integer from 1 to 10.

In Chemical Formula 2, when m is 2 or more, non-adjacent —CR^{p}R^{q}— may be replaced with oxygen (—O—).

The epoxy-containing groups, E¹ and E², of Chemical Formula 2 may be a functional group represented by one of Chemical Formulae (2A) to (2H).

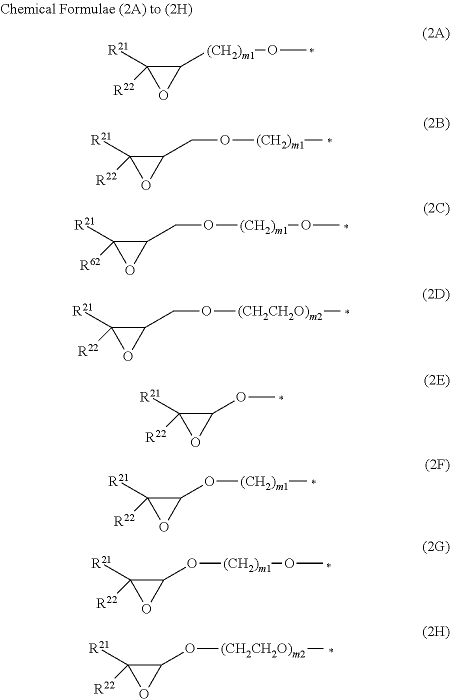

In Chemical Formulae (2A) to (2H),
R²¹ and R²² are each independently hydrogen, deuterium, a halogen, a C1 to C10 alkyl group, or a C1 to C10 haloalkyl group, and
m1 and m2 are each independently an integer from 1 to 5.

The first compound may be a compound represented by Chemical Formula 3 or Chemical Formula 4.

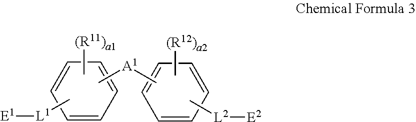

In Chemical Formula 3,
A¹, L¹, L², E¹, and E² are the same as defined in Chemical Formula 1,
R¹¹ and R¹² are each independently hydrogen, deuterium, a C1 to C10 alkyl group, or a C1 to C10 haloalkyl group, and
a1 and a2 are each independently an integer from 0 to 4.

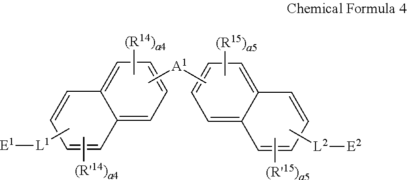

In Chemical Formula 4,
A¹, L¹, L², E¹, and E² are the same as described in Chemical Formula 1,
R¹⁴, R¹⁵, R′¹⁴ and R′¹⁵ are each independently hydrogen, deuterium, a C1 to C10 alkyl group, or a C1 to C10 haloalkyl group, and
a4 and a5 are each independently an integer from 0 to 3.

Non-limiting examples of the compound represented by Chemical Formula 1 may include compounds of Group 1.

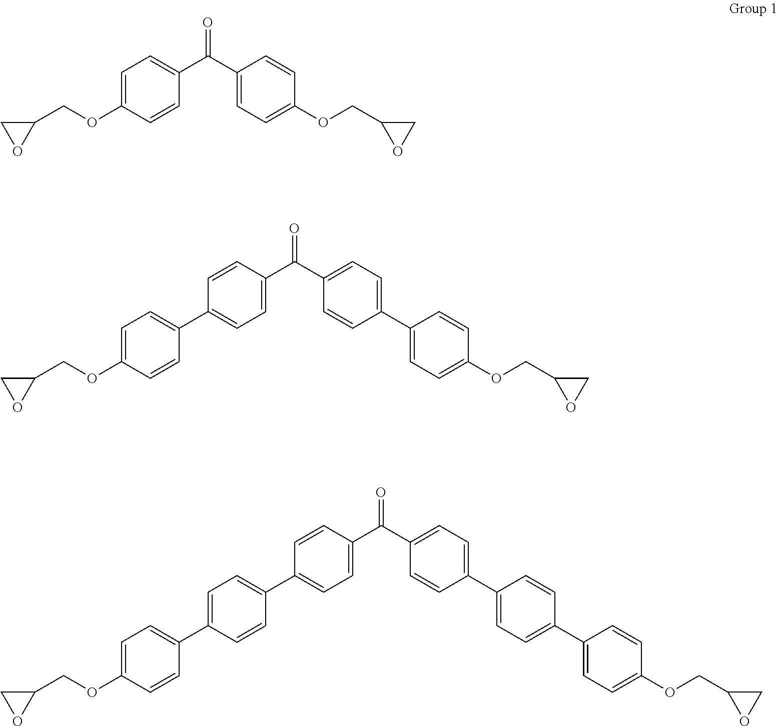 [SMILES: O=C(c1ccc(OCC2CO2)cc1)c1ccc(OCC2CO2)cc1 ; O=C(c1ccc(-c2ccc(OCC3CO3)cc2)cc1)c1ccc(-c2ccc(OCC3CO3)cc2)cc1 ; O=C(c1ccc(-c2ccc(-c3ccc(OCC4CO4)cc3)cc2)cc1)c1ccc(-c2ccc(-c3ccc(OCC4CO4)cc3)cc2)cc1]

The second compound is a low-molecular-weight compound having a molecular weight of about 160 g/mol to about 400 g/mol, as determined by gel permeation chromatography (GPC). The molecular weight of the second compound may be greater than or equal to about 160 g/mol, greater than or equal to about 170 g/mol, greater than or equal to about 180 g/mol, greater than or equal to about 190 g/mol, or greater than or equal to about 200 g/mol and less than or equal to about 400 g/mol, less than or equal to about 390 g/mol, less than or equal to about 380 g/mol, less than or equal to about 370 g/mol, less than or equal to about 360 g/mol, or less than or equal to about 350 g/mol, as determined by GPC. The molecular weight may be confirmed by GPC (gel permeation chromatography) analysis, and specifically, it refers to the average molecular weight calculated by dissolving the molecule in a solvent (e.g., tetrahydrofuran (THF)), then putting it into an analysis column, and analyzing the calibration curve for the developed solution. Within the above range, the hydrogen bond between A¹ of the first epoxy group-containing compound and A² of the second cyclic group-containing compound may be well formed, and the intermolecular compatibility may be improved when forming a eutectic mixture.

The first compound may be used in an amount of greater than or equal to about 30 mol %, greater than or equal to about 35 mol %, greater than or equal to about 40 mol %, greater than or equal to about 45 mol %, and less than or equal to about 55 mol %, less than or equal to about 60 mol % based on a total 100 mol % of the first compound and the second compound, and for example, may be used in an amount of greater than or equal to about 30 mol % and less than or equal to about 60 mol %, based on a total 100 mol % of the first compound and the second compound. A eutectic mixture having low viscosity and phase transition temperature within the above range may be provided.

The second compound may be represented by Chemical Formula 5.

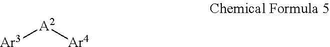

In Chemical Formula 5,
A² is a functional group capable of forming a hydrogen bond with A¹ in Chemical Formula 1 and is —N(H)—, —O(H)—, —S(H)—, C(═O)—, —C(═O)O—, —OC(═O)—, —OC(═O)O—, —N═CR^{a}—, —N═N—, —CR^{b}═N—, —CR^{c}═CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c}, R^{d}, R^{e}, and R^{f} are each independently hydrogen, deuterium, a C1 to C10 alkyl group, or a C1 to C10 haloalkyl group, and
Ar³ and Ar⁴ are each independently a substituted or unsubstituted C6 to C30 aryl group (e.g., a substituted or unsubstituted C6 to C20 aryl group or a substituted or unsubstituted C6 to C10 aryl group), a substituted or unsubstituted C2 to C30 heteroaryl group (e.g., a substituted or unsubstituted C2 to C20 heteroaryl group or a substituted or unsubstituted C2 to C10 heteroaryl group), a substituted or unsubstituted C3 to C30 cycloalkyl group (e.g., a substituted or unsubstituted C3 to C20 cycloalkyl group or a substituted or unsubstituted C3 to C10 cycloalkyl group), C2 to C30 heterocycloalkyl group (e.g., a substituted or unsubstituted C2 to C20 heterocycloalkyl group or a substituted or unsubstituted C2 to C10 heterocycloalkyl group), or a combination thereof.

In Chemical Formula 5, Ar³ and Ar⁴ may each independently be a phenyl group, a naphthyl group, an anthracenyl group, a diphenyl group, a triphenyl group, or a fluorenyl group.

In Chemical Formula 5, Ar³ and Ar⁴ may each independently be a moiety represented by one of Chemical Formulae (5A) to (5I).

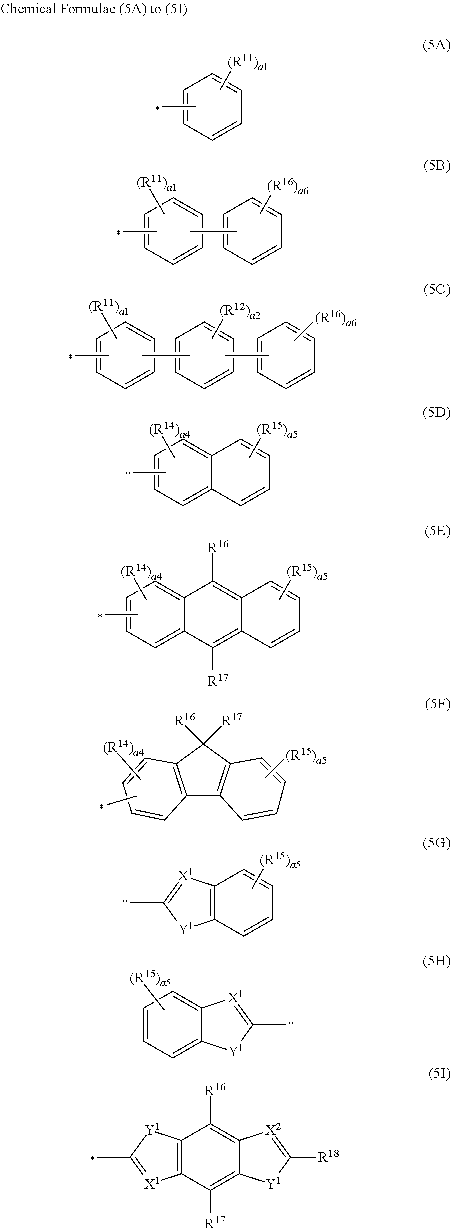

In Chemical Formulae (5A) to (5I),
R¹¹, R¹², R¹³, R¹⁴, R¹⁵, R¹⁶, R¹⁷, and R¹⁸ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, a3, and a5 are each independently an integer from 0 to 4,
a4 is an integer from 0 to 3,
a6 is an integer from 0 to 5, and
* indicates a linking point with Chemical Formula 5.

Non-limiting examples of compounds represented by Chemical Formula may include compounds of Group 2.

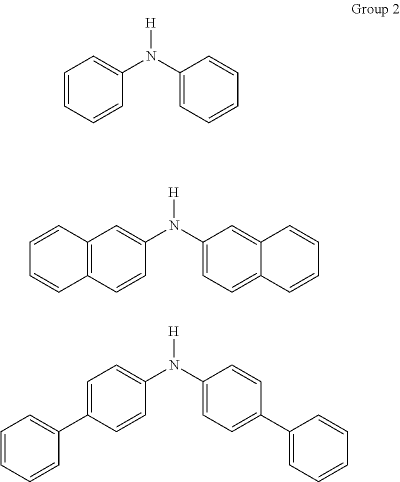 [SMILES: c1ccc(Nc2ccccc2)cc1 ; c1ccc2cc(Nc3ccc4ccccc4c3)ccc2c1 ; c1ccc(-c2ccc(Nc3ccc(-c4ccccc4)cc3)cc2)cc1]

A² of the second compound may form a hydrogen bond with A¹ of the first compound to provide a eutectic mixture having low viscosity and phase transition temperature.

A compound length of the second compound may be greater than or equal to about 8.0 Å, greater than or equal to about 9.0 Å, greater than or equal to about 10.0 Å, greater than or equal to about 11.0 Å, greater than or equal to about 12.0 Å, greater than or equal to about 13.0 Å, greater than or equal to about 14.0 Å, or greater than or equal to about 15.0 Å and less than or equal to about 25 Å, less than or equal to about 24 Å, less than or equal to about 23 Å, less than or equal to about 22 Å, less than or equal to about 21 Å, or less than or equal to about 20 Å, and may be for example in a range of about 8.0 Å to about 25 Å, as determined by DFT. Here, the compound length means a distance from Ar³ to Ar⁴ when Ar³ and Ar⁴ in Chemical Formula 5 are unsubstituted, and may be confirmed by calculating the molecular skeleton of an energetically optimized structure through Density Functional Theory (DFT) calculations and measuring the longest length of the compound in that molecular skeleton. Within the above range, the hydrogen bond between A¹ of the first compound and A² of the second compound may be well formed, and the intermolecular compatibility may be improved when forming a eutectic mixture.

The second compound may be included in the curable composition in an amount of greater than or equal to about 40 mol %, greater than or equal to about 45 mol %, greater than or equal to about 50 mol %, greater than or equal to about 55 mol %, and less than or equal to about 60 mol %, or less than or equal to about 70 mol %, based on a total 100 mol % of the mixture of the first compound and the second compound, and may be for example included in an amount of greater than or equal to about 20 mol % and less than or equal to about 70 mol % or greater than or equal to about 30 mol % and less than or equal to about 60 mol %. A eutectic mixture having low viscosity and phase transition temperature within the above range may be provided.

The curable composition may have a phase transition temperature of greater than or equal to about −30° C., greater than or equal to about −25° C., greater than or equal to about −20° C., greater than or equal to about −15° C. or greater than or equal to about −10° C. and less than or equal to about 50° C., less than or equal to about 45° C., less than or equal to about 40° C., less than or equal to about 35° C., or less than or equal to about 30° C., and may have for example a phase transition temperature in a range of about −30° C. to about 50° C. This is a considerably lower temperature compared to the melting point of the first compound (for example, the melting point of DBPE (4,4′-dihydroxybenzophenone epoxy) is 135° C.). Since the first functional group of the first compound and the second functional group of the second compound form a hydrogen bond, the curable composition may have a lower phase transition temperature than the melting point of the first compound.

The mixture of the first compound and the second compound may have a low complex viscosity of less than or equal to about 10 Pa·s at a temperature of less than or equal to about 100° C. (e.g., 98° C.). For example, the mixture of the first compound and the second compound may have a complex viscosity of greater than or equal to about 0.01 Pa·s, greater than or equal to about 0.02 Pa·s, greater than or equal to about 0.03 Pa·s, greater than or equal to about 0.04 Pa·s, or greater than or equal to about 0.05 Pa·s and less than or equal to about 10 Pa·s, less than or equal to about 9.9 Pa·s, less than or equal to about 9.8 Pa·s, less than or equal to about 9.7 Pa·s, less than or equal to about 9.6 Pa·s, or less than or equal to about 9.5 Pa·s at a temperature of less than or equal to about 100° C. (e.g., 98° C.). For example, the complex viscosity of the mixture of the first compound and the second compound may be in a range of about 0.01 Pa·s to about 10 Pa·s, for example about 0.02 Pa·s to about 9.5 Pa·s, at a temperature of less than or equal to about 100° C. (e.g., 98° C.). By having such a low viscosity, the processability may be improved, and the dispersibility may be improved when preparing a curable composition or a composition for forming a composite including the same. The complex viscosity may be measured, for example, by a rheometer (e.g., a parallel plate oscillatory rheometer). The complex viscosity according to temperature change may be measured under the conditions of a heating rate of 2° C./min, a strain of 5%, and an angular frequency of 1 Hz.

The mixture of the first compound and the second compound may be prepared by mixing the first compound and the second compound in the aforementioned amounts and then stirring at about 50° C. to about 140° C. for about 10 to about 60 hours. In the mixture of the first compound and the second compound that is prepared in this manner, a hydrogen bond is formed between the first functional group of the first compound and the second functional group of the second compound, so that the mixture can exist in a eutectic mixture state.

The mixture of the first compound and the second compound may be prepared by mixing the first compound and the second compound in a solvent, and the mixing method is not particularly limited. The solvent that can be used may include water, ethanol, methanol, butanol, isopropyl alcohol, tetrahydrofuran, 1,4-dioxane, dimethyl sulfoxide, or the like. The temperature during mixing may be from about 25° C. to about 90° C., but embodiments are not limited thereto.

The curing agent may be a compound containing at least one amino group in the molecule, and the curing agent may include an aliphatic amine, an aromatic amine, an alicyclic amine, or a combination thereof, and may include a primary amine, a secondary amine, a tertiary amine, or the like.

Non-limiting examples of the curing agent may include an aliphatic amine such as dicyandiamide, diethylenetriamine, triethylenetetramine, tetraethylenepentamine, dipropylenediamine, diethylaminopropylamine, dimethylaminopropylamine, hexamethylenediamine, and 1,2-bis(2-aminoethoxy) ethane; alicyclic amine such as isophoronediamine, N-aminoethylpiperazine, benzenediamine, diaminodicyclohexylmethane, 1,3-diaminomethylcyclohexane, or the like; an aromatic amine such as imidazole, metaphenylenediamine, 1,3-benzenedimethaneamine, 1,3-diaminotoluene, 1,4-diaminotoluene, 2,4-diaminotoluene, 3,5-diethyl-2,4-diaminotoluene, 3,5-diethyl-2,6-diaminotoluene, 2,4-diaminoanisole, 4,4-diaminodiphenylmethane (DDM), 2,4′-diaminodiphenylmethane, 4,4′-diaminodiphenylsulfone (DDS), 2,6-dimethylaniline, 4,4′-methylenebis(2-ethylaniline), 3,3′-diethyl-4,4′-diaminodiphenylmethane, 3,3′,5,5′-tetramethyl-4,4′-diaminodiphenylmethane, 3,3′,5,5′-tetraethyl-4,4′-diaminodiphenylmethane, polytetramethylene oxide di-para-aminobenzoate, m-xylylenediamine; a condensation reaction product of the aromatic amines with epichlorohydrin; a reaction product of the aromatic amine with styrene, or the like.

Non-limiting examples of the curing agent may include one or more compounds of Group 3, but embodiments are not limited thereto:

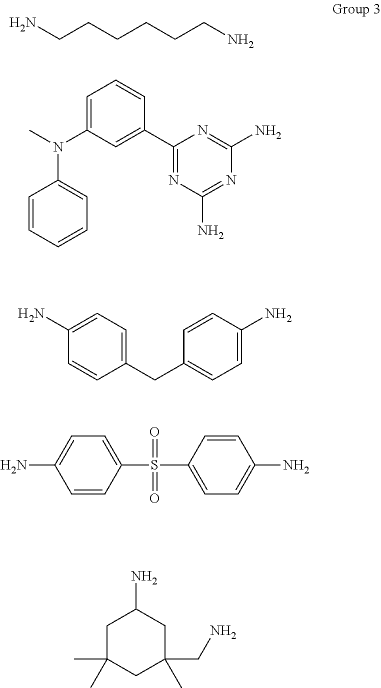

In the curable composition, the curing agent may be included in an amount of greater than or equal to about 10 parts by weight, greater than or equal to about 15 parts by weight, greater than or equal to about 20 parts by weight, greater than or equal to about 25 parts by weight, or greater than or equal to about 30 parts by weight and less than or equal to about 90 parts by weight, less than or equal to about 85 parts by weight, less than or equal to about 80 parts by weight, less than or equal to about 75 parts by weight, less than or equal to about 70 parts by weight, less than or equal to about 65 parts by weight, or less than or equal to about 60 parts by weight, based on 100 parts by weight of the mixture of the first compound and the second compound (a total amount of the first compound having the first functional group and the second compound having the second functional group) and may be included in an amount of, for example about 10 to about 90 parts by weight, for example about 20 to about 80 parts by weight, about 10 to about 70 parts by weight, about 30 to about 80 parts by weight, about 30 to about 70 parts by weight, or about 30 to about 60 parts by weight based on 100 parts by weight of the mixture of the first compound and the second compound. Within the above range, the curing rate of the curing agent may be increased while minimizing the amount of unreacted curing agent, thereby preventing the insulating properties of the composite from being deteriorated.

As the phase transition temperature of the aforementioned curable composition is lowered, the range of the curing temperature of the curing agent may be wider than before. Therefore, the curing temperature of the curing agent may not be particularly limited, and for example, the curing temperature of the curing agent may be greater than or equal to about 25° C., greater than or equal to about 30° C., greater than or equal to about 35° C., greater than or equal to about 40° C., greater than or equal to about 45° C., or greater than or equal to about 50° C. and less than or equal to about 250° C., less than or equal to about 240° C., less than or equal to about 230° C., less than or equal to about 220° C., less than or equal to about 210° C., less than or equal to about 200° C., less than or equal to about 190° C., less than or equal to about 180° C., less than or equal to about 170° C., less than or equal to about 160° C., or less than or equal to about 150° C., and may be in the range of, for example about 25° C. to about 250° C., about 60° C. to about 180° C., about 25° C. to about 130° C., about 25° C. to about 110° C. or about 25° C. to about 100° C. Since it is possible to use a curing agent that initiates the curing reaction even at such low temperatures, the choice range of curing agent may be expanded.

The curable composition may have a complex viscosity of greater than or equal to about 40 Pa·s, greater than or equal to about 50 Pa·s, greater than or equal to about 60 Pa·s, greater than or equal to about 70 Pa·s, greater than or equal to about 80 Pa·s, greater than or equal to about 90 Pa·s, greater than or equal to about 100 Pa·s, greater than or equal to about 110 Pa·s, greater than or equal to about 120 Pa·s, or greater than or equal to about 130 Pa·s and less than or equal to about 400 Pa·s, less than or equal to about 390 Pa·s, less than or equal to about 380 Pa·s, less than or equal to about 370 Pa·s, less than or equal to about 360 Pa·s, less than or equal to about 350 Pa·s, or less than or equal to about 340 Pa·s at a temperature of less than or equal to about 100° C. (e.g., 98° C.). For example, the complex viscosity of the curable composition may be in a range of about 40 Pa·s to about 200 Pa·s, for example about 60 Pa·s to about 150 Pa·s, at a temperature of less than or equal to about 100° C. (e.g., 98° C.). By having such a low viscosity, the processability may be improved, and the dispersibility and filling rate of the filler may be improved when preparing a composition for forming a composite as described herein. The complex viscosity may be measured, for example, by a rheometer (e.g., a parallel plate oscillatory rheometer). The complex viscosity according to temperature change may be measured under the conditions of a heating rate of 2° C./min, a strain rate of 5%, and an angular frequency of 1 Hz.

The curing composition may exhibit an exothermic peak having an onset temperature of curing (onset temperature) of 25° C. to 130° C. in a differential scanning calorimetry (DSC) graph, and may substantially not exhibit an endothermic peak in the temperature range in which the exothermic peak appears. That is, since the mixture of the first compound, the second compound, and the curing agent is in a liquid state before the curing start temperature (onset temperature), an endothermic peak may not appear after the curing start temperature (onset temperature). Here, “substantially no endothermic peak” means that there is no peak in the DSC graph where the heat flow value decreases relative to the baseline.

The curing composition may have a maximum exothermic peak by differential scanning calorimetry (DSC) of greater than or equal to about 0° C., greater than or equal to about 5° C., greater than or equal to about 10° C., greater than or equal to about 15° C., greater than or equal to about 20° C., greater than or equal to about 25° C., greater than or equal to about 30° C., greater than or equal to about 35° C., greater than or equal to about 40° C., greater than or equal to about 45° C., or greater than or equal to about 50° C. and less than or equal to about 200° C., less than or equal to about 195° C., less than or equal to about 190° C., or less than or equal to about 180° C., and may be for example in a range of about 0° C. to about 200° C., about 20° C. to about 180° C., about 50° C. to about 180° C., or about 80° C. to about 180° C.

The curable composition may further include a filler.

Here, the filler may include an inorganic filler, an organic filler, or a combination thereof.

The inorganic filler may include a metal, a metal alloy, an oxide, a nitride, an oxynitride, a carbonate, clay, glass fiber, ceramic, or a combination thereof.

Non-limiting examples of the inorganic filler may include a metal such as gallium (Ga), indium (In), tin (Sn), silver, copper, gold, aluminum, nickel, zinc, or the like; an alloy of two or more of the above metals, silica, boron oxide, alumina, magnesia, alumina (Al₂O₃), zinc oxide (ZnO), magnesium oxide (MgO), titania (TiO₂), antimony oxide, silicon nitride, boron nitride (BN, for example hexagonal boron nitride (h-BN) or boron nitride nanotube), aluminum nitride (AlN), carbon nitride, silicon oxynitride, boron oxynitride, calcium silicate, calcium carbonate, magnesium carbonate, clay, talc, glass fiber, eucryptite ceramic, diamond, carbon nanotube (CNT), graphene, graphene oxide, reduced graphene oxide, or a combination thereof, but embodiments are not limited thereto. The eucryptite ceramic may be a crystallized glass composed of Li₂O, Al₂O₃, and SiO₂ components.

The inorganic filler may be spherical, oval, tubular, plate-shaped (sheet-shaped), or flake-shaped.

The organic filler may include at least one of polyethyleneimine, ethylene glycol, or polyethylene glycol, but embodiments are not limited thereto.

The filler may be included in an amount of greater than or equal to about 40 wt %, greater than or equal to about 45 wt %, greater than or equal to about 50 wt %, greater than or equal to about 55 wt %, greater than or equal to about 60 wt %, greater than or equal to about 65 wt %, greater than or equal to about 70 wt %, greater than or equal to about 75 wt %, or greater than or equal to about 80 wt %, and less than or equal to about 95 wt %, less than or equal to about 90 wt %, less than or equal to about 85 wt %, less than or equal to about 80 wt %, less than or equal to about 75 wt %, or less than or equal to about 70 wt %, based on 100 wt % of the curable composition (including the filler). For example, the filler may be included in an amount of about 40 wt % to about 95 wt %, about 40 wt % to about 90 wt %, about 40 wt % to about 70 wt %, about 40 wt % to about 60 wt %, about 70 wt % to about 95 wt %, about 80 wt % to about 95 wt %, or about or 80 wt % to 92 wt %, based on 100 wt % of the curable composition (including the filler). Within the above range, the thermal conductivity may be improved while ensuring the dispersibility of the curable composition. Even when the amount of the filler is increased to 95 wt %, the filler may be excellently dispersed, and a degree of alignment of the filler in the composite (cured product of the curable composition) manufactured therefrom may be increased, thereby exhibiting excellent thermal conductivity.

When the curable composition includes a filler, that is, the curable composition including a mixture of the first compound and the second compound, the curing agent, and the filler, may have a complex viscosity in a range of greater than or equal to about 50 Pa·s, greater than or equal to about 60 Pa·s, greater than or equal to about 70 Pa·s, greater than or equal to about 80 Pa·s, greater than or equal to about 90 Pa·s, greater than or equal to about 100 Pa·s, greater than or equal to about 110 Pa·s, greater than or equal to about 120 Pa·s, or greater than or equal to about 130 Pa·s and less than or equal to about 400 Pa·s, less than or equal to about 390 Pa·s, less than or equal to about 380 Pa·s, less than or equal to about 370 Pa·s, less than or equal to about 360 Pa·s, less than or equal to about 350 Pa·s, or less than or equal to about 340 Pa·s at a temperature of less than or equal to about 100° C. (e.g., 98° C.), and may have for example a complex viscosity in a range of about 50 Pa·s to about 400 Pa·s, about 60 Pa·s to about 400 Pa·s, about 70 Pa·s to about 400 Pa·s, about 80 Pa·s to about 400 Pa·s, about 90 Pa·s to about 400 Pa·s, or about 100 Pa·s to about 200 Pa·s at a temperature of less than or equal to about 100° C. (e.g., 98° C.). The complex viscosity may be measured, for example, by a rheometer (e.g., a parallel plate oscillatory rheometer). The complex viscosity according to temperature change may be measured under the conditions of a heating rate of 2° C./min, a strain rate of 5%, and an angular frequency of 1 Hz.

The curable composition may further include at least one additive that may be a curing accelerator, a reaction regulator, a release agent, a coupling agent, a stress reliever, an auxiliary flame retardant, or the like, as needed.

Another aspect provides a composite including a cured product of the aforementioned curable composition and optionally a filler. The composite may maintain excellent filler dispersibility and filling rate, and may have a high thermal conductivity and good mechanical properties even when including a high content of the filler. For example, the composite may have a thermal conductivity of greater than or equal to about 0.35 W/mK, for example greater than or equal to about 0.5 W/mK or greater than or equal to about 0.6 W/mK, as measured by the Transient Plane Source (TPS) method in the isotropic mode. In one or more embodiments, the composite may have a thermal conductivity of less than or equal to about 16 W/mK. For example, the composite may have a thermal conductivity of greater than or equal to about 0.35 W/mK and less than or equal to about 16 W/mK, as measured by a Transient Plane Source method in an isotropic mode.

Another aspect provides a method for manufacturing a composite, including: curing the curable composition including the aforementioned curable composition and optionally a filler at a curing temperature of about 25° C. to about 250° C. As described above, since the curable composition includes a eutectic mixture of the first compound and the second compound, a curing reaction may be performed at a low temperature to produce a composite. For example, the curing temperature may be about 25° C. to about 250° C., about 60° C. to about 180° C., about 25° C. to about 130° C., about 25° C. to about 110° C., or about 25° C. to about 100° C. These curing temperatures have an expanded range compared to conventional ones in the art.

A semiconductor package may be manufactured using the aforementioned curable composition.

A semiconductor package may be provided on a printed circuit board on which the semiconductor chip is mounted by sealing the semiconductor chip with a molding portion in order to protect the semiconductor chip from the external environment, have insulating properties, and effectively dissipate heat during operation of the chip. In this case, the molding portion may be formed by coating the curable composition according to the embodiment as a molding composition for a semiconductor package.

In addition, the semiconductor packages may be vertically connected to each other through solder bumps electrically connecting the semiconductor packages formed using the composition to form a package-on-package type of semiconductor package.

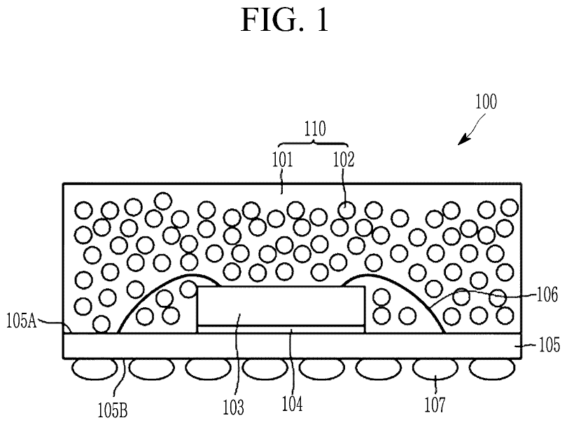

FIG. 1 is a cross-sectional view showing a schematic configuration of a semiconductor package 100 according to one or more embodiments.

Referring to FIG. 1, the semiconductor package 100 includes a substrate 105; a die attach film 104 on the substrate 105; a chip 103 disposed on the substrate 105 and attached to the substrate 105 through the die attach film 104; a connection portion 106 such as a bonding wire for electrically connecting the chip 103 and the substrate 105 to each other; and a molding portion 110 configured to encapsulate the chip 103 and the connection portion 106 and to protect the substrate 105 and a mounting structure including the chip 103 and the connection portion 106 mounted on the substrate 105.

The molding portion 110 may be formed on the substrate 105 to completely cover the chip 103 and the connection portion 106.

The molding portion 110 is obtained from the curable composition (molding composition for a semiconductor package) according to the aforementioned embodiment. The molding portion 110 may include a molding resin 101 and a plurality of fillers 102 dispersed in the molding resin 101. The molding resin 101 may be formed by curing the aforementioned curable composition using the curing agent. That is, the molding portion 110 may have a form in which the fillers 102 are dispersed within a matrix formed by curing the aforementioned curable composition using the curing agent. These fillers 102 may be omitted in some embodiments (not shown).

On a surface 105B of the substrate 105 opposite to the mounting surface 105A of the substrate 105 on which the chip 103 is mounted, a plurality of solder balls 107 is formed to electrically connect the chip 103 with an external circuit (not shown).

When the composition may be used to manufacture, for example, the semiconductor package 100 shown in FIG. 1, a low-pressure transfer molding process may be used to form the molding portion 110 sealing the chip 103 mounted on the substrate 105. However, the present embodiment is not limited thereto but may use, for example, an injection molding process or a casting process instead of the low-pressure transfer molding process.

The curable composition according to one or more embodiments may protect a chip region in the semiconductor package from moisture. Accordingly, reliability of the semiconductor package may be improved under a relatively humid environment.

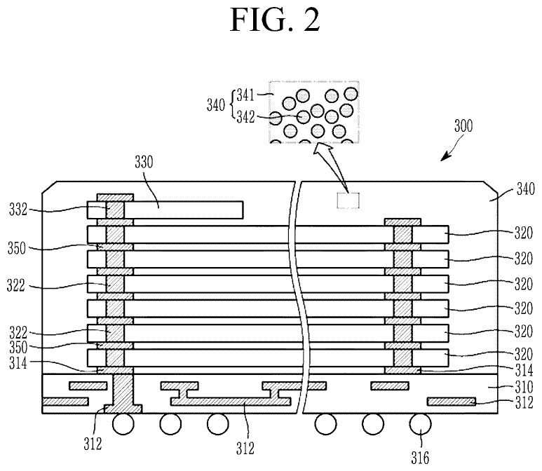

FIG. 2 is a cross-sectional view showing a schematic configuration of an integrated circuit device 300 according to one or more embodiments.

Referring to FIG. 2, the integrated circuit device 300 includes a plurality of semiconductor chips 320 sequentially stacked on a package substrate 310. A control chip 330 is connected onto the plurality of semiconductor chips 320. A stacking structure of the plurality of semiconductor chips 320 and the control chip 330 on the package substrate 310 is sealed with a molding portion 340. The molding portion 340 may have a similar configuration to the molding portion 110 with reference to FIG. 1. The molding portion 340 may be formed by using the aforementioned curable composition (molding composition for semiconductor package) according to one or more embodiments. The molding portion 340 may include a molding resin 341 and a plurality of fillers 342 that are dispersed in the molding resin 341. The molding resin 341 and the plurality of fillers 342, with reference to FIG. 1, are the same as the molding resin 101 and the plurality of fillers 102.

FIG. 2 illustrates a structure where six semiconductor chips 320 are vertically stacked, but the number and stacking directions of the semiconductor chips 320 are not limited thereto. The number of semiconductor chips 320 may be smaller or larger than 6. The plurality of semiconductor chips 320 may be aligned in a horizontal direction, a vertical direction, or a combination thereof on the package substrate 310. In one or more embodiments, the control chip 330 may be omitted.

The package substrate 310 may be configured to have a flexible printed circuit (FPC) board, a rigid printed circuit board, or a combination thereof. The package substrate 310 includes an internal wire 312 and a connection terminal 314. The connection terminal 314 may be formed on one surface of the package substrate 310. On the other surface of the package substrate 310, a solder ball 316 is formed. The connection terminal 314 is electrically connected to the solder ball 316 through the internal wire 312.

In one or more embodiments, the solder ball 316 may be replaced with a conductive bump or LGA (lead grid array).

The plurality of semiconductor chips 320 and the control chip 330 respectively include a connection structure 322 and 332, respectively. In one or more embodiments, the connection structure 322 and 332 may be a TSV (through silicon via) contact structure.

Each connection structure 322 and 332 of the plurality of semiconductor chips 320 and the control chip 330 may be electrically connected to the connection terminal 314 of the package substrate 310 through a connection portion 350.

The plurality of semiconductor chips 320 respectively may include a system LSI, a flash memory, DRAM, SRAM, EEPROM, PRAM, MRAM, or RRAM. The control chip 330 may include a logic circuit such as a SER/DES (serializer/deserializer) circuit, but embodiments are not limited thereto.

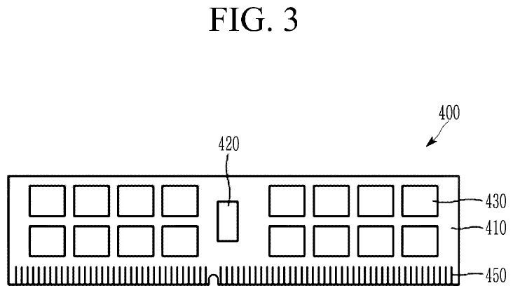

FIG. 3 is a plan view illustrating a schematic configuration of an integrated circuit device 400 according to one or more embodiments.

The integrated circuit device 400 includes a module substrate 410 and a control chip 420 and a plurality of semiconductor packages 430 mounted on the module substrate 410. In the module substrate 410, a plurality of input/output terminals 450 are formed.

The plurality of semiconductor packages 430 includes at least either one of the semiconductor package 100 shown in FIG. 1 or the integrated circuit device 300 shown in FIG. 2.

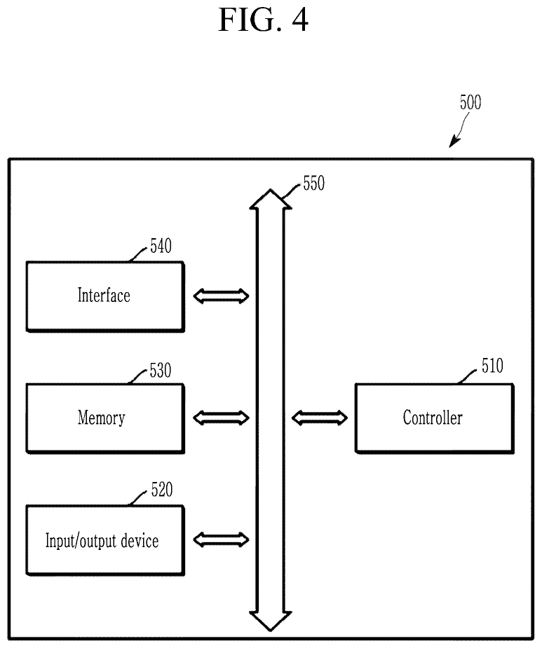

FIG. 4 is a diagram illustrating a schematic configuration of an integrated circuit device 500 according to one or more embodiments.

The integrated circuit device 500 includes a controller 510, an input/output device 520, a memory 530, and an interface 540. The integrated circuit device 500 may be a mobile system or a system for transmitting or receiving information. In one or more embodiments, the mobile system is at least one of PDA (personal digital assistant), a portable computer, a web tablet, a wireless phone, a mobile phone, a digital music player, or a memory card, but embodiments are not limited thereto.

In one or more embodiments, the controller 510 is a microprocessor, a digital signal processor, or a micro-controller.

The input/output device 520 is used for data input/output of the integrated circuit device 500. The integrated circuit device 500 may be connected to an external device, for example, a personal computer or a network by using the input/output device 520 and exchange data with the external device. In embodiments, the input/output device 520 is a keypad, a keyboard, or a display device (display).

In embodiments, the memory 530 stores codes and/or data for operating the controller 510. In another embodiment, the memory 530 stores data processed in the controller 510. At least one of the controller 510 and memory 530 includes at least one of the semiconductor package 100 shown in FIG. 1 and the integrated circuit device 300 shown in FIG. 2.

The interface 540 serves as a data transmission path between the integrated circuit device 500 and another external device. The controller 510, the input/output device 520, the memory 530, and the interface 540 may communicate one another through a bus 550.

The integrated circuit device 500 may be included in a mobile phone, an MP3 player, a navigation system, a portable multimedia player (PMP), a solid-phase disk (SSD), or household appliances, but embodiments are not limited thereto.

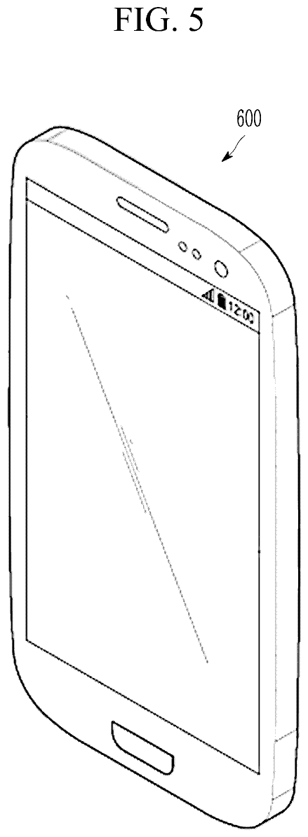

FIG. 5 is a diagram schematically illustrating a mobile wireless phone 600 according to one or more embodiments

The mobile wireless phone 600 includes at least one of the semiconductor package 100 shown in FIG. 1, the integrated circuit device 300 shown in FIG. 2, the integrated circuit device 400 shown in FIG. 3, or the integrated circuit elements 500 shown in FIG. 4.

Hereinafter, the embodiments are illustrated in further detail with reference to examples. However, these examples are exemplary, and the present scope is not limited thereto.

### EXAMPLES

### Synthesis Example 1: Synthesis of First Compound

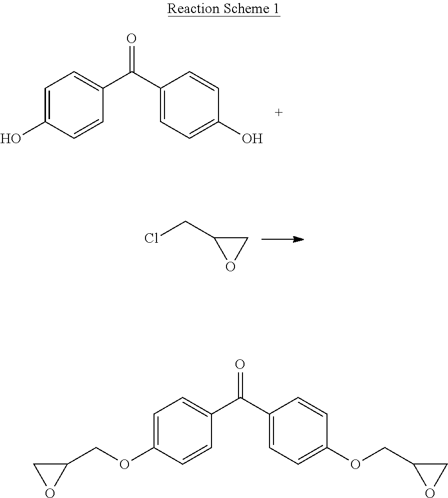 [SMILES: O=C(c1ccc(O)cc1)c1ccc(O)cc1 ; ClCC1CO1 ; O=C(c1ccc(OCC2CO2)cc1)c1ccc(OCC2CO2)cc1]

2 grams (g) of 4,4′-dihydroxybenzophenone and 0.75 g of sodium hydroxide were added to a flask. Subsequently, 200 milliliters (mL) of methanol and epichlorohydrin were added to the flask and then, the mixture was reacted at 60° C. to 90° C. for 3 hours. After the reaction, the resultant product was washed with water and methanol, and dried to obtain 4,4′-dihydroxybenzophenone epoxy (DBPE).

### Examples 1A to 9A: Preparation of Mixtures

Each eutectic mixture according to Examples 1A to 9A was prepared by mixing DBPE obtained in Synthesis Example 1 and diphenylamine (DPA) in each mole ratio of 10:90 (1A), 20:80 (2A), 30:70 (3A), 40:60 (4A), 50:50 (5A), 60:40 (6A), 70:30 (7A), 80:20 (8A), and 90:10 (9A) and then, stirring each mixture at 60° C. to 100° C. for 12 hours to 24 hours.

### Examples 1B to 9B: Preparation of Curable Compositions

17 parts by weight of isophorone diamine (a curing agent) was added based on 100 parts by weight of each mixture according to Examples 1A to 9A and then, stirred at 75° C., preparing each curable composition (1B to 9B).

### Examples 1C-1 to 9C-1: Preparation of Curable Compositions Including Filler

10 wt % of h-BN was added to each of the curable compositions of Examples 1B to 9B and then, stirred at 75° C. to prepare each curable composition including a filler (1C-1 to 9C-1).

### Examples 1C-2 to 9C-2 to Examples 1C-8 to 9C-8: Preparation of Curable Compositions Including Fillers

Each curable composition including a filler was prepared in the same manner as in Examples 1C-1 to 9C-1, except that the h-BN was added in each amount of 20 wt % (1C-2 to 9C-2), 30 wt % (1C-3 to 9C-3), 40 wt % (1C-4 to 9C-4), 50 wt % (1C-5 to 9C-5), 60 wt % (1C-6 to 9C-6), 70 wt % (1C-7 to 9C-7), and 80 wt % (1C-8 to 9C-8) to each of the curable compositions of Examples 1B to 9B.

### Comparative Example 1: Preparation of Curable Composition

A curable composition was prepared by mixing 100 parts by weight of DBPE according to Synthesis Example 1 and 26 parts by weight of isophorone diamine (a curing agent) and then, stirring the mixture at 75° C.

### Comparative Example 2: Preparation of Curable Composition

A curable composition was prepared by mixing 100 parts by weight of DGEBA (diglycidyl ether of bisphenol A) and 23 parts by weight of isophorone diamine (a curing agent) and then, stirring the mixture at 75° C.

### Comparative Example 2C-1: Preparation of Curable Composition Including Filler

A curable composition was prepared by mixing 100 parts by weight of DGEBA (diglycidyl ether of bisphenol A) and 23 parts by weight of isophorone diamine (a curing agent, IPDA), adding 10 wt % of h-BN thereto, and stirring the mixture at 75° C.

### Comparative Examples 2C-2 to 2C-8: Preparation of Curable Compositions Including Fillers

Each curable composition including a filler was prepared in the same manner as in Comparative Example 2C-1 except that the h-BN added after mixing 100 parts by weight of DGEBA (diglycidyl ether of bisphenol A) and 23 parts by weight of isophorone diamine (a curing agent) was added in each amount of 20 wt % (2C-2), 30 wt % (2C-3), 40 wt % (2C-4), 50 wt % (2C-5), 60 wt % (2C-6), 70 wt % (2C-7), and 80 wt % (2C-8).

### Evaluation 1: DSC Evaluation of Mixtures

The mixtures according to Examples 3A to 6A were measured with respect to a phase transition temperature at a heating and cooling speed of 0.1° C./min through differential scanning calorimetry (DSC), and the results are shown in Table 1. For comparison, a melting point of DBPE of Synthesis Example 1 is also described.

TABLE 1

| | | | | | Melting |
|---|---|---|---|---|---|
| | Example | Example | Example | Example | point |
| | 3A | 4A | 5A | 6A | of DBPE |
| Phase | −28.34° C. | −21.87° C. | −12.76° C. | −13.63° C. | 134.42° C. |
| transition | | | | | |
| temperature | | | | | |

Referring to Table 1, the mixtures of Examples 3A to 6A exhibited a significantly lower phase transition temperature than DBPE alone.

### Evaluation 2: DSC Evaluation of Curable Compositions

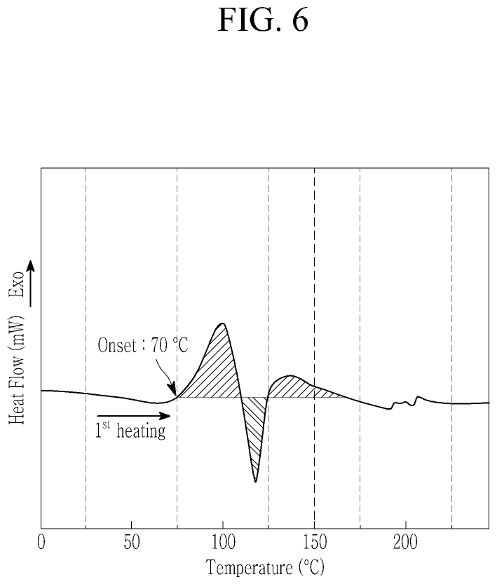

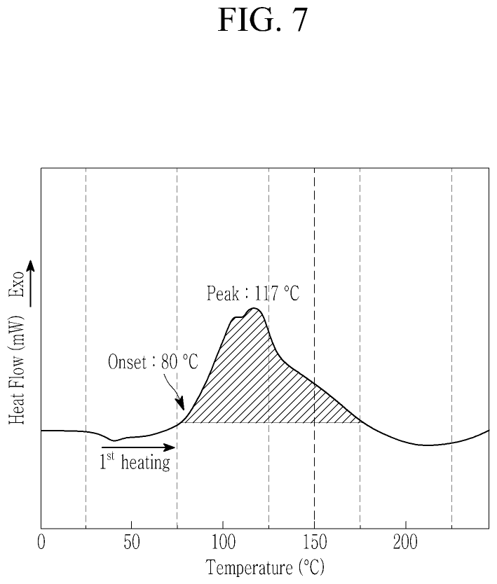

The DSC result of the curable composition of Comparative Example 1 is shown in FIG. 6, and the DSC (at a heating and cooling speed of 10° C./min) result of the curable composition Example 5B is shown in FIG. 7.

Referring to FIG. 6, the curable composition of Comparative Example 1 started to be cured at about 70° C. (an onset temperature of curing), wherein an exothermic peak due to the curing was overlapped with an endothermic peak due to melting of DBPE. In other words, the endothermic peak appears with a decreasing heat flow within a temperature range (about 70° C. to about 170° C.) of the exothermic peak. On the other hand, in the curable composition of Example 5B shown in FIG. 7, both the eutectic mixture and IPDA (a curing agent) are melted before the curing onset temperature (at about 80° C.) and exhibit a maximum exothermic peak of 117° C. within an exothermic peak temperature range (about 70° C. to about 175° C.), but with no separate endothermic peak.

### Evaluation 3: Complex Viscosity of Mixtures

The mixture of Example 5A was measured with respect to complex viscosity according to a temperature change at a speed of 2° C./min, a strain rate of 5%, and an angular frequency of 1 Hz by using a rheometer (Discovery HR30, TA Instrument, New Castle, DE, USA), the results of which are shown in Table 2.

TABLE 2

| | | | | | |
|---|---|---|---|---|---|
| Measurement | 60 | 70 | 80 | 90 | 100 |
| temperature | | | | | |
| (° C.) | | | | | |
| Complex | 9.2 | 2.2 | 0.7 | 0.4 | 0.03 |
| viscosity of | | | | | |
| Example 5A | | | | | |
| (Pa · s) | | | | | |

Referring to Table 2, the mixture of Example 5A exhibited low viscosity at 60° C. to 100° C. DBPE exists as a solid phase at 60° C. to 100° C., but the mixture of Example 5A exists as a liquid composition with low viscosity.

### Evaluation 4: Complex Viscosity of Curable Compositions

The curable composition of Example 5B was measured with respect to complex viscosity according to a temperature change at a heating speed of 2° C./min, a strain rate of 5%, and each frequency of 1 Hz by using a rheometer (Discovery HR30, TA Instrument, New Castle, DE, USA). The viscosity measured at 98° C. is shown in Table 3.

TABLE 3

| | |
|---|---|
| Measurement temperature (° C.) | 98 |
| Complex viscosity of Example 5B | 150 |
| (Pa · s) | |

Referring to Table 3, the curable composition of Example 5B exhibited lower viscosity of 150 Pa·s at 98° C. For comparison, the curable composition of Comparative Example 1, a mixture of DBPE/IPDA, was measured with respect to complex viscosity, which turns out to be immeasurable, because DBPE exists in a solid state at 98° C.

### Evaluation 5: Transparency of Curable Composition

The curable compositions (Examples 5C-1, 5C-2, 5C-3, 5C-4, 5C-5, 5C-6, 5C-7, and 5C-8) prepared by adding h-BN to the curable composition of Example 5B (DBPE:DPA=50:50 in a mole ratio) and that of Comparative Example 2C-1 were respectively placed in a disk-shaped mold and then, heated at 80° C. for 30 minutes and thermal pressure-molded at 110° C. under 5 MPa at 2 hours, manufacturing specimens.

When the manufactured specimens were measured with respect to transparency with visual inspection, the specimens of the curable compositions according to Examples 5C-1, 50-2, 5C-3, 5C-4, 50-5, 50-6, 5C-7, and 5C-8 exhibited an overall even color and a color that was close to white. This confirmed that h-BN was evenly dispersed.

On the other hand, the specimen formed of the curable composition of Comparative Example 2C-1 exhibited a non-uniform color, a partial stain, and a dark yellow color. This confirmed that h-BN was not evenly dispersed.

Evaluation 6: Thermal Conductivity of Cured Product Prepared from Curable Composition

The curable composition of Comparative Example 1 was placed in a disk-shaped mold and heated at 80° C. for 30 minutes and then, thermal pressure-molded at 110° C. under 5 MPa for 2 hours, manufacturing a specimen.

The curable composition of Example 5B (DBPE:DPA=50:50 in a mole ratio) was placed in a disk-shaped mold and heated at 80° C. for 30 minutes and then, thermal pressure-molded at 110° C. under 5 MPa for 2 hours, manufacturing a specimen.

The curable compositions (Examples 5C-1, 5C-2, 5C-3, 5C-4, 50-5, 5C-6, 5C-7 and 5C-8) prepared by adding h-BN to the curable composition of Example 5B and that of Comparative Example 2C-1 were respectively placed in a disk-shaped mold and heated at 80° C. for 30 minutes and then, thermal pressure-molded at 110° C. under 5 MPa for 2 hours, manufacturing specimens.

The specimens of Comparative Example 1 and Examples 5B, 5C-1, 5C-2, 50-3, 50-4, 50-5, 50-6, 50-7, and 50-8 were measured with respect to thermal conductivity, as follows.

The thermal conductivity was evaluated in the following method. The thermal conductivity was measured by using a thermal content analyzer of Hot Disc TPS 2500 (ThermTest Inc., Sweden) in a transient plane source (TPS) method. The thermal conductivity of each specimen was measured three times. The measurement of each specimen was performed by setting time to 1 to 10 seconds at a frequency of 60 Hz with an exothermic energy amount of 10 mW to 500 mW.

The measurement results are shown in Table 4. The thermal conductivity of Table 4 was an arithmetic mean of the three measurements.

TABLE 4

| | Thermal | | Thermal |
|---|---|---|---|
| Curable | conductivity | Curable | conductivity |
| composition | (W/mk) | composition | (W/mK) |
| Comparative | 0.24 | Comparative | 0.21 |
| Example 1 | | Example 2 | |
| (DBPE/IPDA) | | (DGEBA/IPDA) | |
| Example 5C-1 | 0.37 | Comparative | 0.25 |
| | | Example 2C-1 | |
| Example 5C-2 | 0.61 | Comparative | 0.30 |
| | | Example 2C-2 | |
| Example 5C-3 | 1.10 | Comparative | 0.38 |
| | | Example 2C-3 | |
| Example 5C-4 | 1.51 | Comparative | 0.53 |
| | | Example 2C-4 | |
| Example 5C-5 | 2.40 | Comparative | 0.72 |
| | | Example 2C-5 | |
| Example 5C-6 | 3.20 | Comparative | 1.0 |
| | | Example 2C-6 | |
| Example 5C-7 | 8.00 | Comparative | unmeasurable |
| | | Example 2C-7 | |
| Example 5C-8 | 15.91 | Comparative | unmeasurable |
| | | Example 2C-8 | |

Referring to Table 4, the specimens of Examples 5C-1 to 5C-8, even when h-BN is added up to 80 wt %, were manufactured, and the specimens of the curable compositions according to Examples 5C-1 to 50-8 exhibit increased thermal conductivity as compared with the specimen of the curable composition according to Comparative Example 1.

On the other hand, the specimens of the curable compositions of Comparative Examples 2C-1 to 2C-8 exhibited a slightly increased thermal conductivity from that of Comparative Example 2C-1 prepared by adding 10 wt % of h-BN to that of Comparative Example 2C-6 prepared by adding 60 wt % of h-BN. The curable compositions of Comparative Examples 2C-7 and 2C-8, prepared respectively by adding 70 wt % or 80 wt % of h-BN, were not successfully manufactured into specimens, and therefore thermal conductivity was immeasurable.

In the results of Table 4, the curable compositions of Examples 5C-1 to 5C-8, in which the mixtures of Examples 1A to 9A existed in a liquid eutectic mixture state and thus well penetrated between h-BN and thereby, well formed a heat transfer path, which confirmed that thermal conductivity thereof was improved.

Evaluation 7: Thermal Conductivity of Cured Product Prepared from Curable Composition

The curable composition of Comparative Example 1 was placed in a disk-shaped mold and heated at 80° C. for 30 minutes and then, thermal pressure-molded at 110° C. under 5 MPa for 2 hours, manufacturing a specimen.

The curable composition of Example 5B (DBPE:DPA=50:50 in a mole ratio) was placed in a disk-shaped mold and heated at 80° C. for 30 minutes and then, thermal pressure-molded at 110° C. under 5 MPa for 2 hours, manufacturing a specimen.

The specimens manufactured respectively by using the curable compositions of Comparative Example 1 and Example 5B were measured with respect to tensile strength and tensile strain by using a universal testing machine (UTM), and the results are shown in Table 5.

TABLE 5

| | Tensile | Tensile |
|---|---|---|
| | strength | strain |
| | (MPa) | (%) |
| Comparative | 7.2 | 1.0 |
| Example 1 | | |
| (DBPE/IPDA) | | |
| Example 5B | 44.3 | 12.4 |

Referring to Table 5, the specimen manufactured by using the curable composition of Example 5B, compared with the specimen manufactured by using the curable composition of Comparative Example 1, exhibited significantly greater tensile strength and tensile strain.

While this disclosure has been described in connection with what is presently considered to be practical exemplary embodiments, it is to be understood that the subject matter is not limited to the disclosed embodiments. On the contrary, it is intended to cover various modifications and equivalent arrangements included within the spirit and scope of the appended claims.

What is claimed is:

1. A curable composition, comprising
a first compound, wherein the first compound is an epoxy group-containing compound comprising a first functional group,
a second compound, wherein the second compound is a cyclic group-containing compound comprising a second functional group, and
a curing agent,
wherein one of the first functional group or the second functional group comprises a hydrogen bond accepting group, and the other of the first functional group or the second functional group comprises a hydrogen bond donating group,
the first functional group and the second functional group form a hydrogen bond with each other, and
the second compound has a molecular weight of about 160 grams per mole to about 400 grams per mole, as determined by gel permeation chromatography.

2. The curable composition of claim 1, wherein
the first compound and the second compound form a eutectic mixture at a temperature below the melting point of the first compound.

3. The curable composition of claim 1, wherein
the first compound is represented by Chemical Formula 1: 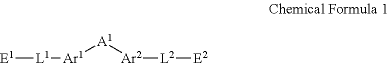
wherein, in Chemical Formula 1,
A¹ is —C(═O)—, —C(═O)O—, —OC(═O)—, —OC(═O)O—, —N═CR^{a}—, —N═N—, —CR^{b}═N—, —CR^{c}═CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c}, R^{d}, R^{e}, and R^{f} are each independently hydrogen, deuterium, a C1 to C10 alkyl group, or a C1 to C10 haloalkyl group,
L¹ and L² are each independently a single bond, —O—, —C(═O)—, —C(═O)O—, —OC(═O)—, —OC(═O)O—, —CR^{c}═CR^{d}—C(═O)—, —S(═O)—, —S(═O)₂—, —CH═N—, —NR^{e}C(═O)O—, —C(═O)NR^{f}—, or —OC(═O)NHS(═O)O— wherein R^{c}, R^{d}, R^{e}, and R^{f} are each independently hydrogen, deuterium, a C1 to C10 alkyl group, or a C1 to C10 haloalkyl group,
Ar¹ and Ar² are each independently a substituted or unsubstituted C6 to C30 arylene group, a substituted or unsubstituted C2 to C30 heteroarylene group, a substituted or unsubstituted C3 to C30 cycloalkylene group, C2 to C30 heterocycloalkylene group, or a combination thereof, and
E¹ and E² are each independently an epoxy-containing group.

4. The curable composition of claim 3, wherein
in Chemical Formula 1, Ar¹ and Ar² are each independently a moiety represented by one of Chemical Formulae (1A) to (1I): 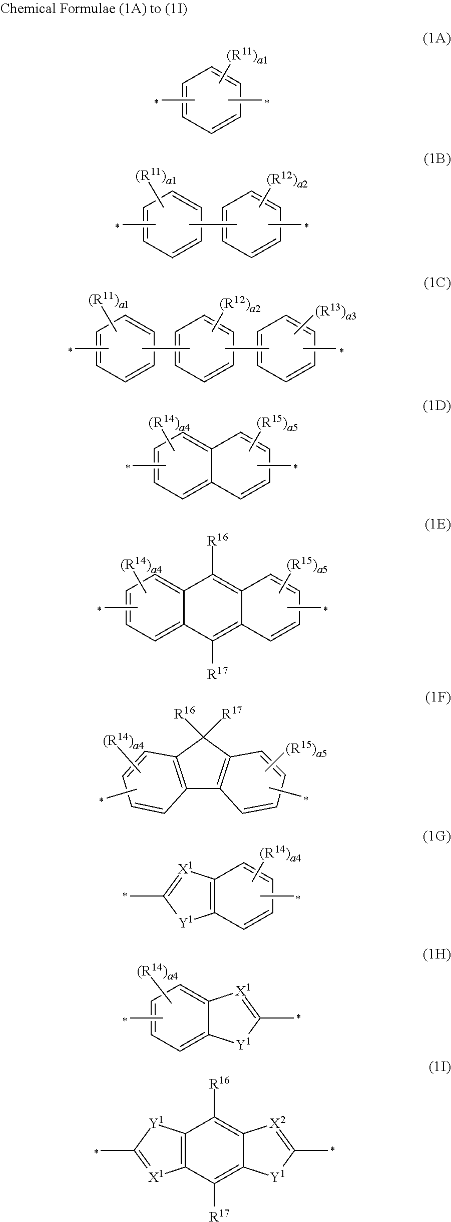
wherein, in Chemical Formulae (1A) to (1I),
R¹¹, R¹², R¹³, R¹⁴, R¹⁵, R¹⁶, and R¹⁷ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, and a3 are each independently an integer from 0 to 4,
a4 and a5 are each independently an integer from 0 to 3, and
* indicates a linking point with Chemical Formula 1.

5. The curable composition of claim 1, wherein
the second compound is represented by Chemical Formula 5: 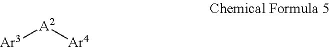
wherein, in Chemical Formula 5,
A² is a functional group capable of forming a hydrogen bond with A¹ in Chemical Formula 1 and comprises —N(H)—, —O(H)—, —S(H)—, C(═O)—, —C(═O)O—, —OC(═O)—, —OC(═O)O—, —N═CR^{a}—, —N═N—, —CR^{b}═N—, —CR^{c}—CR^{d}—C(═O)—, —S(═O)—, —S(═O)₂—, —NR^{e}C(═O)O—, —C(═O)NR^{f}—, or —OC(═O)NHS(═O)O—, wherein R^{a}, R^{b}, R^{c},
R^{d}, R^{e}, and R^{f} are each independently hydrogen, deuterium, a C1 to C10 alkyl group, or a C1 to C10 haloalkyl group, and
Ar³ and Ar⁴ are each independently a substituted or unsubstituted C6 to C30 aryl group, C2 to C30 heteroaryl group, a substituted or unsubstituted C3 to C30 cycloalkyl group, C2 to C30 heterocycloalkyl group, or a combination thereof.

6. The curable composition of claim 5, wherein
in Chemical Formula 5, Ar³ and Ar⁴ are each independently a moiety represented by one of Chemical Formulae (5A) to (5I): 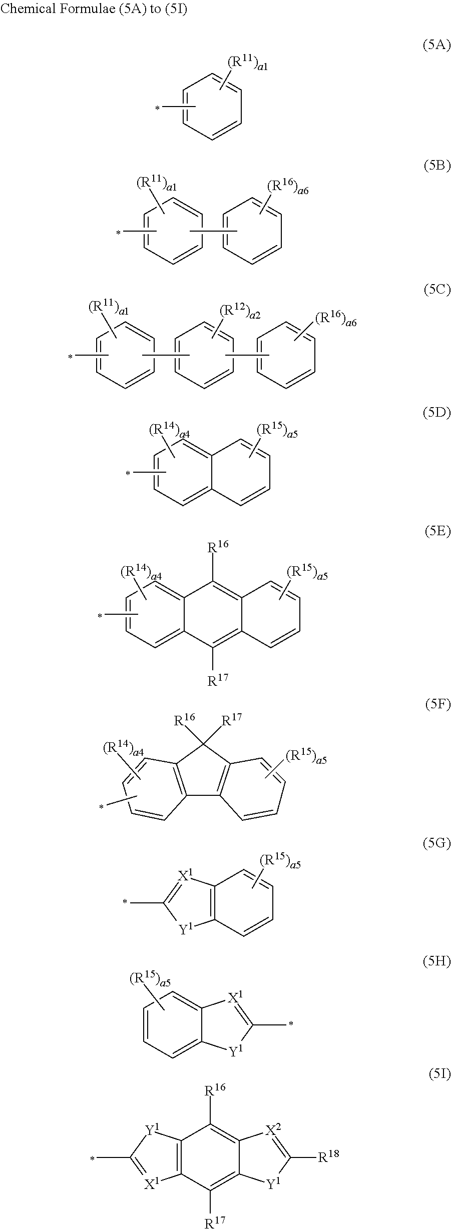
wherein, in Chemical Formulae (5A) to (5I),
R¹¹, R¹², R¹³, R¹⁴, R¹⁵, R¹⁶, R¹⁷, and R¹⁸ are each independently hydrogen, deuterium, a C1 to C10 alkyl group, or a C1 to C10 haloalkyl group,
X¹ and X² are each independently CR^{x}, N, P, or As, wherein R^{x} is hydrogen, deuterium, a C1 to C10 alkyl group, or a C1 to C10 haloalkyl group,
Y¹ and Y² are each independently O, S, Se, or Te,
a1, a2, a3, and a5 are each independently an integer from 0 to 4,
a4 is an integer from 0 to 3,
a6 is an integer from 0 to 5, and
* indicates a linking point with Chemical Formula 5.

7. The curable composition of claim 1, wherein
the second compound has a compound length of about 8.0 angstroms to about 25 angstroms, as determined by Density Functional Theory.

8. The curable composition of claim 1, wherein
the curable composition comprises the first compound in an amount of about 30 mole percent to about 60 mole percent, based on a total of 100 mole percent of the first compound and the second compound.

9. The curable composition of claim 1, wherein
the curable composition has a phase transition temperature of about −30° C. to about 50° C.

10. The curable composition of claim 1, wherein
the curing agent comprises an aliphatic amine, an aromatic amine, an alicyclic amine, or a combination thereof.

11. The curable composition of claim 1, wherein
the curable composition comprises the curing agent in an amount of about 10 parts by weight to about 90 parts by weight, based on 100 parts by weight of a total amount of the first compound and the second compound.

12. The curable composition of claim 1, wherein
a curing temperature of the curing agent is about 25° C. to about 250° C.

13. The curable composition of claim 1, wherein
the curable composition shows an exothermic peak with an onset temperature from about 25° C. to about 130° C. in a differential scanning calorimetry graph, and
an endothermic peak does not substantially appear in the temperature range where the exothermic peak is shown.

14. The curable composition of claim 1, wherein
the curable composition further comprises an inorganic filler, and
the inorganic filler comprises a metal, a metal alloy, an oxide, a nitride, an oxynitride, a carbonate, a clay, a glass fiber, a ceramic, or a combination thereof.

15. The curable composition of claim 14, wherein
the curable composition comprises the inorganic filler in an amount of about 40 weight percent to about 95 weight percent, based on 100 weight percent of the curable composition.

16. The curable composition of claim 14, wherein
the curable composition has a complex viscosity of less than or equal to about 400 Pascal seconds at a temperature of less than or equal to about 100° C., as determined by a rheometer at a heating rate of 2° C./min, a strain of 5%, and an angular frequency of 1 Hertz.

17. A composite, comprising a cured product of the curable composition according to claim 1.

18. A method of manufacturing a composite, comprising curing a curable composition at a temperature of about 25° C. to about 250° C.,
wherein the curable composition comprises:
a first compound, wherein the first compound is an epoxy group-containing compound comprising a first functional group,
a second compound, wherein the second compound is a cyclic group-containing compound comprising a second functional group, and
a curing agent,
wherein one of the first functional group or the second functional group comprises a hydrogen bond accepting group, and the other of the first functional group or the second functional group comprises a hydrogen bond donating group,
the first functional group and the second functional group form a hydrogen bond with each other, and
the second compound has a molecular weight of about 160 grams per mole to about 400 grams per mole, as determined by gel permeation chromatography.

19. A semiconductor package, comprising a cured product of a curable composition,
wherein the curable composition comprises:
a first compound, wherein the first compound is an epoxy group-containing compound comprising a first functional group,
a second compound, wherein the second compound is a cyclic group-containing compound comprising a second functional group, and
a curing agent,
wherein one of the first functional group or the second functional group comprises a hydrogen bond accepting group, and the other of the first functional group or the second functional group comprises a hydrogen bond donating group,
the first functional group and the second functional group form a hydrogen bond with each other, and
the second compound has a molecular weight of about 160 grams per mole to about 400 grams per mole, as determined by gel permeation chromatography.

20. An electronic device, comprising a cured product of the curable composition according to claim 1.
